(19) United States
(12) Patent Application Publication
(10) Pub. No.: US 2024/0258436 A1
(43) Pub. Date: Aug. 1, 2024

(54) DISPLAY DEVICE AND METHOD OF MANUFACTURING THE DISPLAY DEVICE

(71) Applicant: Samsung Display Co., Ltd., Yongin-Si (KR)

(72) Inventors: SOYOUNG KOO, Yongin-si (KR); TAEWOOK KANG, Yongin-si (KR); Hyoung Do Kim, Yongin-si (KR); HYUNGJUN KIM, Yongin-si (KR); YUNYONG NAM, Yongin-si (KR); JUN HYUNG LIM, Yongin-si (KR); Ki-Lim Han, Yongin-si (KR)

(21) Appl. No.: 18/380,678

(22) Filed: Oct. 17, 2023

(30) Foreign Application Priority Data
Jan. 27, 2023 (KR) 10-2023-0011098

(51) Int. Cl. H01L 29/786; H01L 29/423; H01L 29/66

(52) U.S. Cl. CPC H01L 29/78696; H01L 29/42384; H01L 29/66742; H01L 29/7869

(57) ABSTRACT

A display device includes: a buffer layer including an inorganic insulating material, an active pattern disposed on the buffer layer and including a channel region and a first conductor region adjacent to the channel region, a gate insulating layer disposed on the buffer layer and the active pattern and including an inorganic insulating material, a gate electrode layer including a first electrode extending along a side surface of the gate insulating layer and including a first contact portion electrically contacting the first conductor region, and an oxygen supply layer including a first pattern disposed between the first electrode and the gate insulating layer, wherein the first pattern includes a first groove recessed from a side surface of to surround at least a part of the first contact portion in a plan view.

### CROSS-REFERENCE TO RELATED APPLICATION

This application claims priority to and benefits of Korean Patent Application No. 10-2023-0011098 under 35 U.S.C. § 119, filed on Jan. 27, 2023, in the Korean Intellectual Property Office (KIPO), the entire contents of which are hereby incorporated by reference.

### BACKGROUND

### 1. Field

Embodiments provide generally to a display device and a method of manufacturing the display device.

### 2. Description of the Related Art

A display device is a device that displays an image and may include a pixel arranged in a display area. The pixel may be a minimum unit that emits light, and a plurality of pixels may be provided in the display area.

The pixel may include a light emitting portion and a pixel circuit electrically connected to the light emitting portion to provide a driving current to the light emitting portion. The pixel circuit may include at least one transistor for generating (or transferring) the driving current.

The transistor may include an oxide semiconductor material and at least one electrode electrically contacting (or connected to) the oxide semiconductor material. In this case, when a defect occurs in an electrical connection between the oxide semiconductor material and the electrode, display quality of the display device may deteriorate.

In addition, at least one mask may be used to manufacture a pixel including a transistor. As the number of masks used in the manufacturing process increases, the manufacturing cost of the display device increases, the occurrence of defects in the display device increases, and the efficiency of the manufacturing process may deteriorate.

### SUMMARY

Embodiments provide a display device with improved display quality.

Embodiments provide a method of manufacturing a display device with improved process efficiency.

A display device according to embodiments of the present disclosure includes a buffer layer including an inorganic insulating material, an active pattern disposed on the buffer layer and including a channel region and a first conductor region adjacent to the channel region, a gate insulating layer disposed on the buffer layer and the active pattern and including an inorganic insulating material, a gate electrode layer including a first electrode which includes a first contact portion electrically contacting the first conductor region by extending along a side surface of the gate insulating layer, and an oxygen supply layer including a first pattern disposed between the first electrode and the gate insulating layer, wherein the first patten includes a first groove recessed from a side surface of the first pattern to surround at least a part of the first contact portion in a plan view.

In an embodiment, the first electrode may directly contact an upper surface of the gate insulating layer in an area between an edge of the first pattern defining the first groove and an edge of the first contact portion in the plan view.

In an embodiment, an average taper angle of the side surface of the gate insulating layer with respect to an upper surface of the active pattern may be about 65 degrees or less and about 30 degrees or more.

In an embodiment, the display device may further include a lower electrode layer disposed under the buffer layer and including a first lower electrode electrically connected to the first electrode.

In an embodiment, the first electrode may include a first lower electrode contact portion electrically contacting the first lower electrode through a through hole formed through the gate insulating layer and the buffer layer. The first pattern may include a first opening formed through the first pattern in a thickness direction and exposing the first lower electrode contact portion in the plan view.

In an embodiment, the first electrode may directly contact an upper surface of the gate insulating layer in an area between an edge of the first opening and an edge of the first lower electrode contact portion in the plan view.

In an embodiment, the active pattern may further include a second conductor region spaced apart from the first conductor region with the channel region interposed therebetween. The gate electrode layer may further include a second electrode which includes a second contact portion electrically contacting the second conductor region by extending along a side surface of the gate insulating layer and spaced apart from the first electrode. The oxygen supply layer may further include a second pattern disposed between the second electrode and the gate insulating layer and spaced apart from the first pattern. A second groove recessed from a side surface of the second pattern to surround at least a part of the second contact portion may be defined in the second pattern.

In an embodiment, the second electrode may directly contact an upper surface of the gate insulating layer in an area between an edge of the second pattern defining the second groove and an edge of the second contact portion in the plan view.

In an embodiment, the display device may further include a lower electrode layer disposed under the buffer layer and including a second lower electrode electrically connected to the second electrode.

In an embodiment, the second electrode may include a second lower electrode contact portion electrically contacting the second lower electrode through a through hole formed through the gate insulating layer and the buffer layer. The second pattern may include a second opening formed through the second pattern in a thickness direction and overlapping the second lower electrode contact portion in the plan view.

In an embodiment, the second electrode may directly contact an upper surface of the gate insulating layer in an area between an edge of the second opening and an edge of the second lower electrode contact portion in the plan view.

In an embodiment, the second electrode may further include a gate electrode disposed to overlap the channel region. The oxygen supply layer may further include a third pattern disposed between the gate electrode and the gate insulating layer.

In an embodiment, a side surface of the third pattern may be aligned with a side surface of the gate electrode in a cross-sectional view.

In an embodiment, the side surface of the third pattern may be recessed from a side surface of the gate insulating layer disposed under the third pattern.

In an embodiment, each of the oxygen supply layer and the active pattern may include an oxide semiconductor material.

In an embodiment, the oxygen supply layer may directly contact the gate electrode layer.

A method of manufacturing a display device according to embodiments of the present disclosure includes forming an active pattern on a buffer layer, forming a gate insulating layer on the buffer layer and the active pattern, forming a preliminary oxygen supply layer on the gate insulating layer, forming a first photoresist pattern on the preliminary oxygen supply layer, isotropic etching the preliminary oxygen supply layer using the first photoresist pattern as a mask, forming a first through hole exposing the active pattern through the gate insulating layer by etching the gate insulating layer using the first photoresist pattern as a mask, removing the first photoresist pattern, forming a preliminary gate electrode layer to entirely cover the preliminary oxygen supply layer, forming a second photoresist pattern on the preliminary gate electrode layer, and forming a first electrode including a first contact portion electrically contacting the active pattern by extending along a side surface of the gate insulating layer and a first pattern disposed between the first electrode and the gate insulating layer by etching the preliminary gate electrode layer and the preliminary oxygen supply layer using the second photoresist pattern as a mask.

In an embodiment, in the isotropic etching the preliminary oxygen supply layer, the isotropic etched preliminary oxygen supply layer may define a first active opening completely exposing the first through hole in a plan view. An area of the first active opening may be larger than an area of the first through hole in the plan view.

In an embodiment, in the forming the first electrode and the first pattern, a first groove recessed from a side surface of the first pattern may be defined in the first pattern to surround at least a part of the first contact portion. The first groove may be a part of the first active opening.

In an embodiment, in the forming the first electrode and the first pattern, the first contact portion may electrically contact the active pattern by extending along a part of a side surface of the gate insulating layer defining the first through hole.

In an embodiment, in the forming the preliminary gate electrode layer, the preliminary gate electrode layer may directly contact the gate insulating layer in an area between an edge of the first active opening and an edge of the first through hole in a plan view.

In an embodiment, before the forming the active pattern, the method may further include forming a lower electrode layer including a first lower electrode and forming the buffer layer to entirely cover the lower electrode layer.

In an embodiment, in the isotropic etching the preliminary oxygen supply layer, a first opening formed through the preliminary oxygen supply layer in a thickness direction and at least partially overlapping the first lower electrode may be further formed. In the forming the first through hole, a first lower electrode through hole formed through the gate insulating layer and the buffer layer to expose the first lower electrode and is completely exposed by the first opening in a plan view may be further formed. An area of the first opening may be larger than an area of the first lower electrode through hole in the plan view.

In an embodiment, in the forming the preliminary gate electrode layer, the preliminary gate electrode layer may directly contact the gate insulating layer in an area between an edge of the first opening and an edge of the first lower electrode through hole in the plan view.

In an embodiment, in the forming the first electrode and the first pattern, the first electrode may electrically contact the first lower electrode through the first lower electrode through hole.

In an embodiment, in the forming the first electrode and the first pattern, a gate electrode spaced apart from the active pattern with the gate insulating layer interposed therebetween may be further formed by etching the preliminary gate electrode layer. A third pattern disposed between the gate electrode and the gate insulating layer may be further formed by etching the preliminary oxygen supply layer. A side surface of the third pattern may be aligned with a side surface of the gate electrode in a cross-sectional view.

In an embodiment, e method may further include etching the gate insulating layer using the second photoresist pattern as a mask after the forming the first electrode and the first pattern.

In an embodiment, in the etching the gate insulating layer using the second photoresist pattern as the mask, the side surface of the third pattern may be recessed from a side surface of the gate insulating layer disposed under the third pattern in the cross-sectional view.

In a display device according to embodiments, a first groove recessed from a side surface of the first pattern may be defined in the first pattern to surround at least a part of the first contact portion. Accordingly, a defect may not occur in an electrical connection between the first electrode and the first conductor region.

In a method of manufacturing the display device according to embodiments, an isotropic etching of the preliminary oxygen supply layer may be performed using the first photoresist pattern as a mask. Accordingly, in the forming the entire preliminary gate electrode layer to cover the preliminary oxygen supply layer, which is performed after the isotropic etching, a defect may not occur in the preliminary gate electrode layer.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to an embodiment of the present disclosure.

FIG. 2 is a view for explaining pixels included in the display device of FIG. 1.

FIGS. 3, 4, 5 and 6 are views for explaining the pixel circuit of FIG. 2.

FIG. 7 is a cross-sectional view taken along the line I-I′ of FIG. 6.

FIG. 8 is an enlarged cross-sectional view of area A of FIG. 7.

FIG. 9 is an enlarged cross-sectional view of area B of FIG. 7.

FIGS. 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42 and 43 are views for explaining a method of manufacturing the display device of FIG. 2.

### DETAILED DESCRIPTION OF THE EMBODIMENTS

Hereinafter, a display device and a method of manufacturing the display device according to embodiments of the present disclosure will be explained in detail with reference to the accompanying drawings. The same reference numerals are used for the same components in the drawings, and redundant descriptions of the same components will be omitted.

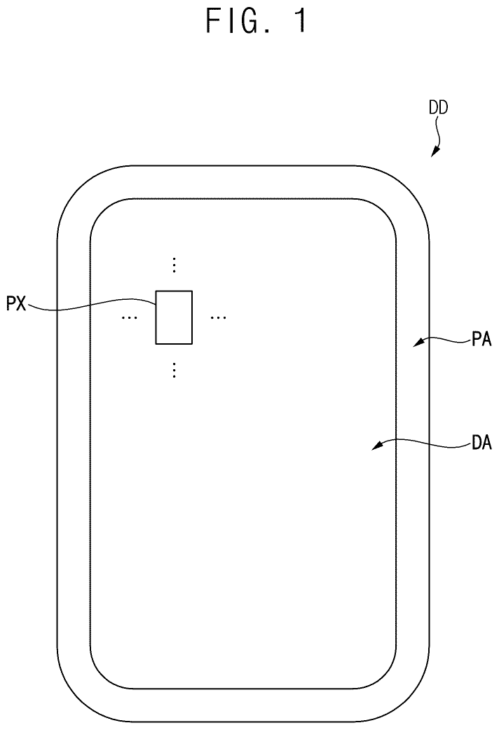

FIG. 1 is a plan view illustrating a display device according to an embodiment of the present disclosure.

The display area DA may be an area where an image is displayed. To this end, a pixel PX which is a minimum unit that emits light may be disposed in the display area DA. A plurality of pixels PX may be provided in the display area DA, and in this case, the plurality of pixels PX may be entirely disposed in the display area DA.

A peripheral area PA may be disposed on at least one side of the display area DA. For example, as shown in FIG. 1, the peripheral area PA may surround the display area DA. A driving circuit portion that generates and/or transmits an electrical signal to the pixel PX may be disposed in the peripheral area PA. In an embodiment, unlike shown in FIG. 1, the peripheral area PA may be omitted. In this case, the driving circuit portion may be disposed on a rear surface of the display area DA.

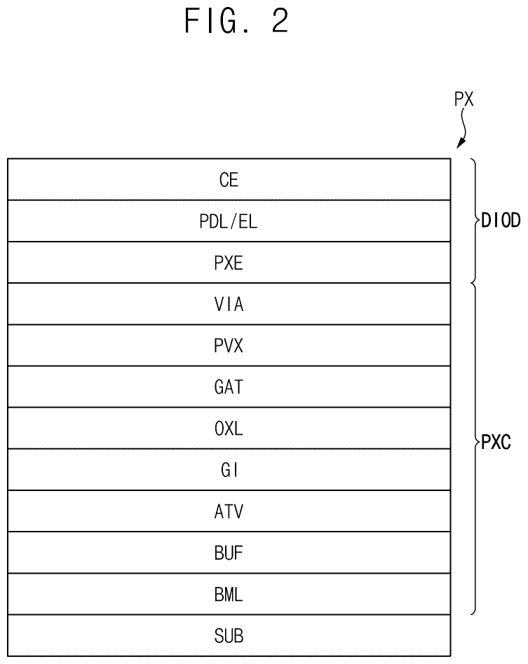

FIG. 2 is a view for explaining pixels included in the display device of FIG. 1.

The pixel PX may include a pixel circuit PXC and a light emitting portion DIOD. The pixel circuit PXC may be electrically connected to the light emitting portion DIOD. Accordingly, the pixel circuit PXC may provide driving current to the light emitting portion DIOD, and the light emitting portion DIOD may emit light having a luminance corresponding to the intensity of the driving current.

The pixel circuit PXC may include at least one insulating layer, at least one conductive layer, and at least one semiconductor material layer disposed on the substrate SUB. For example, the pixel circuit PXC may include a lower electrode layer BML, a buffer layer BUF, an active pattern ATV, a gate insulating layer GI, an oxygen supply layer OXL, a gate electrode layer GAT, a passivation layer PVX, and a via insulating layer VIA disposed on a substrate SUB in a thickness direction.

Each of the lower electrode layer BML and the gate electrode layer GAT may include a conductive material. For example, the conductive material may include silver, an alloy containing silver, aluminum nitride, tungsten, tungsten nitride, copper, indium tin oxide, indium zinc oxide, and the like. These may be used alone or in combination with each other.

Each of the active pattern ATV and the oxygen supply layer OXL may include an oxide semiconductor material. For example, the oxide semiconductor material may include indium-gallium-zinc oxide, indium-gallium oxide, indium-zinc oxide, and the like.

Each of the buffer layer BUF, the gate insulating layer GI, and the passivation layer PVX may include an inorganic insulating material. In addition, the via insulating layer VIA may include an organic insulating material.

The light emitting portion DIOD may be disposed on the pixel circuit PXC. The light emitting portion DIOD may include a pixel electrode PXE, a pixel defining layer PDL, a light emitting layer EL, and a common electrode layer CE.

In an embodiment, the pixel circuit PXC may include at least one transistor for generating (or transmitting) the driving current or compensating for the driving current. The active pattern ATV, the lower electrode layer BML, and the gate electrode layer GAT may constitute the transistor. For example, the active pattern ATV, the lower electrode layer BML, and the gate electrode layer GAT may form a driving transistor electrically connected to the pixel electrode PXE.

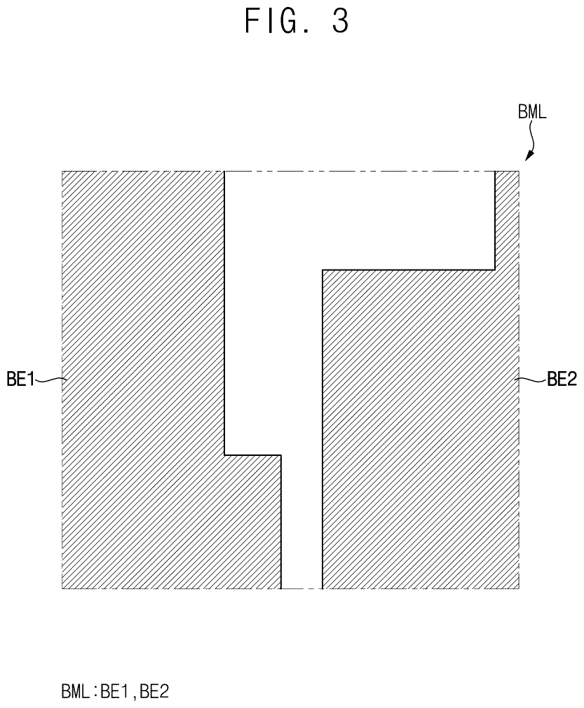

FIGS. 3 to 6 are views for explaining the pixel circuit of FIG. 2.

Referring to FIG. 3, the lower electrode layer BML included in the pixel circuit PXC may include a first lower electrode BE1 and a second lower electrode BE2. As shown in FIG. 3, the first lower electrode BE1 and the second lower electrode BE2 may be spaced apart from each other. In an embodiment, different types of electrical signals may be applied to the first lower electrode BE1 and the second lower electrode BE2.

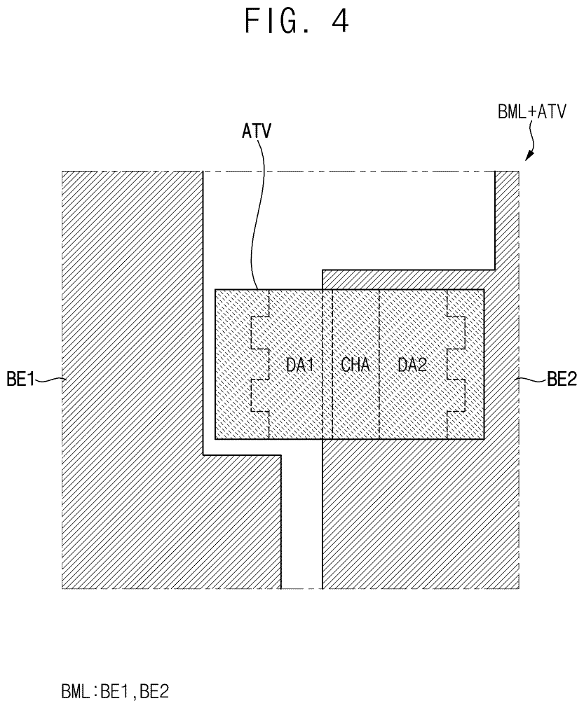

Referring to FIG. 4, the active pattern ATV included in the pixel circuit PXC may be disposed on the lower electrode layer BML.

The active pattern ATV may include a first conductor region DA1 and a second conductor region DA2 having relatively high conductivity. In addition, the active pattern ATV may include a channel region CHA having a relatively low conductivity.

For example, each of the first conductor region DA1 and the second conductor region DA2 may be a doped region doped with impurities, and the channel region CHA may be a non-doped region or a region doped with a lower concentration than the first and second conductor regions DA1 and DA2.

Each of the first and second conductor regions DA1 and DA2 may serve as an electrode, a signal line, and an input terminal and/or an output terminal of a transistor. The channel region CHA may be a region overlapping a gate electrode GE.

As shown in FIG. 4, each of the first and second conductor regions DA1 and DA2 may be disposed adjacent to the channel region CHA, and the first and second conductor regions DA1 and DA2 may be spaced apart from each other with the channel region CHA interposed therebetween.

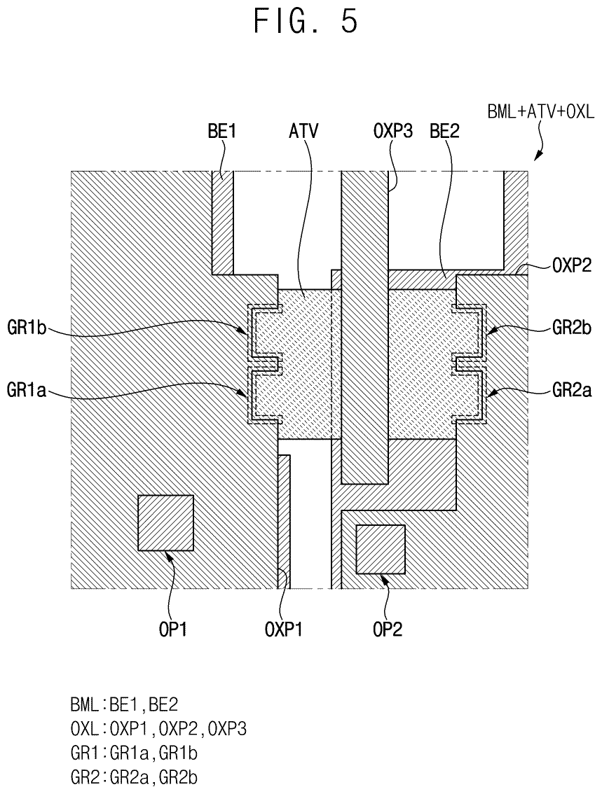

Referring to FIG. 5, the oxygen supply layer OXL included in the pixel circuit PXC may be disposed on the lower electrode layer BML and the active pattern ATV.

The oxygen supply layer OXL may include a first pattern OXP1, a second pattern OXP2, and a third pattern OXP3.

A first opening OP1 formed through the first pattern OXP1 in the thickness direction may be defined in the first pattern OXP1. In this case, the first opening OP1 may overlap the first lower electrode BE1 in a plan view.

In addition, a first groove GR1 recessed from a side surface of the first pattern OXP1 in the plan view may be defined in the first pattern OXP1. In an embodiment, a plurality of first grooves GR1 may be provided. For example, as shown in FIG. 5, two first grooves GRla and GR1b may be defined in the first pattern OXP1. However, this is an example, and only one first groove GR1 may be provided, or three or more first grooves GR1 may be provided in the first pattern OXP1.

A second opening OP2 formed through the second pattern OXP2 in the thickness direction may be defined in the second pattern OXP2. In this case, the second opening OP2 may overlap the second lower electrode BE2 in a plan view.

In addition, a second groove GR2 recessed from a side surface of the second pattern OXP2 in the plan view may be defined in the second pattern OXP2. In an embodiment, a plurality of second grooves GR2 may be provided. For example, as shown in FIG. 5, two second grooves GR2a and GR2b may be defined in the second pattern OXP2. However, this is an example, and only one second groove GR2 may be provided, or three or more second grooves GR2 may be provided in the second pattern OXP2.

The third pattern OXP3 may overlap the channel region CHA of the active pattern ATV.

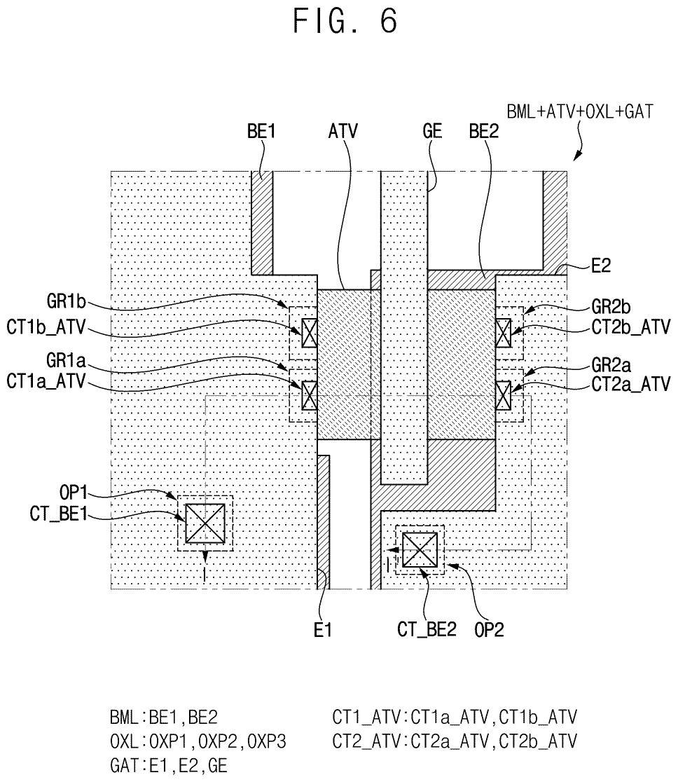

Referring to FIG. 6, the gate electrode layer GAT included in the pixel circuit PXC may be disposed on the lower electrode layer BML, the active pattern ATV, and the oxygen supply layer OXL.

The gate electrode layer GAT may include a first electrode E1, a second electrode E2, and a gate electrode GE.

The first electrode E1 may be disposed on the first pattern OXP1. The first electrode E1 may be electrically connected to the first lower electrode BE1. For example, the first electrode E1 may include a first lower electrode contact portion CT_BE1 electrically contacting the first lower electrode BE1. In addition, the first electrode E1 may electrically contact the first conductor area DA1 of the active pattern ATV. For example, a first active contact portion CT1_ATV electrically contacting the first conductor region DA1 of the active pattern ATV may be defined in the first electrode E1.

In an embodiment, when the plurality of first grooves GR1 are provided, a plurality of first active contact portions CT1_ATV may be provided to correspond to the first grooves GR1. For example, when two first grooves GRla and GR1b are defined in the first pattern OXP1, two first active contact portions CTla_ATV and CT1b_ATV corresponding to the two first grooves GR1a and GR1b may be defined in the first electrode E1.

Hereinafter, for convenience of explanation, the first groove GR1a and the first active contact portion CTla_ATV will be described as references, and descriptions of the first groove GR1b and the first active contact portion CT1b_ATV will be omitted.

The second electrode E2 may be disposed on the second pattern OXP2. The second electrode E2 may be electrically connected to the second lower electrode BE2. For example, the second electrode E2 may include a second lower electrode contact portion CT_BE2 electrically contacting the second lower electrode BE2. In addition, the second electrode E2 may electrically contact the second conductor area DA2 of the active pattern ATV. For example, a second active contact portion CT2_ATV electrically contacting the second conductor region DA2 of the active pattern ATV may be defined in the second electrode E2.

In an embodiment, when the plurality of second grooves GR2 are provided, a plurality of second active contact portions CT2_ATV may be provided to correspond to the second grooves GR2. For example, when two second grooves GR2a and GR2b are defined in the second pattern OXP2, two second active contact portions CT2a_ATV and CT2b ATV corresponding to the second grooves GR2a and GR2b may be defined in the second electrode E2.

Hereinafter, for convenience of explanation, the second groove GR2a and the second active contact portion CT2a_ATV will be described as references, and descriptions of the second groove GR2b and the second active contact portion CT2b_ATV will be omitted.

The gate electrode GE may be disposed on the third pattern OXP3. The gate electrode GE may be disposed to overlap the channel region CHA of the active pattern ATV.

In an embodiment, the first electrode E1, the second electrode E2, the gate electrode GE, and the active pattern ATV may constitute a transistor. For example, the gate electrode GE may serve as a gate electrode of the transistor, the first electrode E1 and the second electrode E2 may serve as an input electrode and an output electrode of the transistor, respectively, the first conductor region DA1 and the second conductor region DA2 may serve as an input terminal and an output terminal of the transistor, respectively, and the channel region CHA may serve as a channel of the transistor.

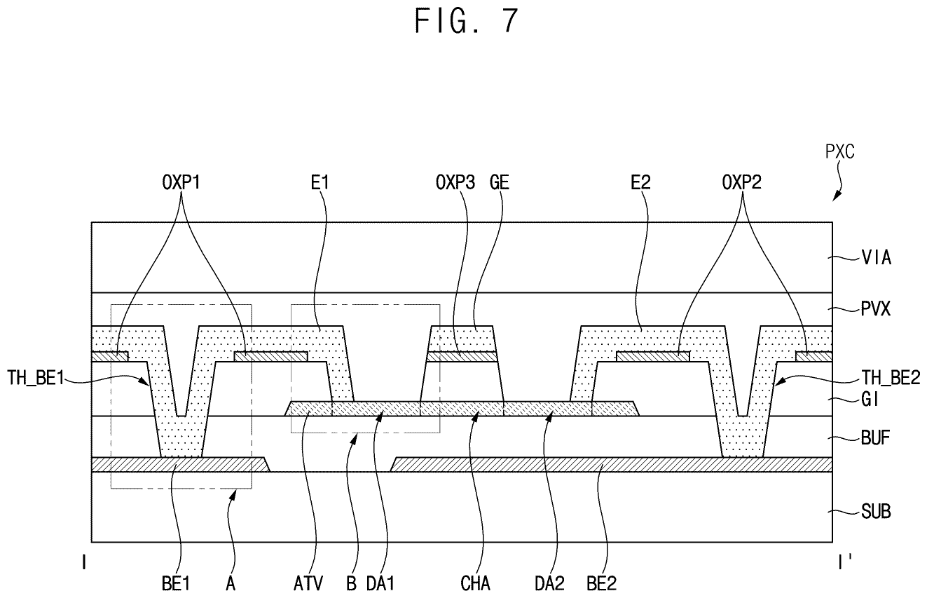

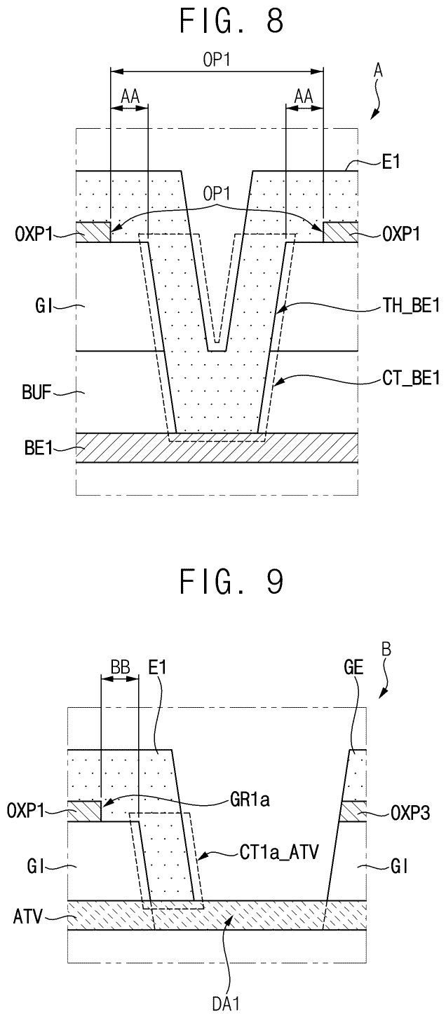

FIG. 7 is a cross-sectional view taken along the line I-I′ of FIG. 6. FIG. 8 is an enlarged cross-sectional view of area A of FIG. 7. FIG. 9 is an enlarged cross-sectional view of area B of FIG. 7.

Referring to FIG. 7, in an embodiment, the oxygen supply layer OXL (OXP1, OXP2 and OXP3) may directly contact the gate electrode layer GAT (GE, E1 and E2).

For example, on the gate insulating layer GI, the first pattern OXP1 may directly contact the first electrode E1, and the second pattern OXP2 may directly contact the second electrode E2, and the third pattern OXP3 may directly contact the gate electrode GE.

As shown in FIG. 7, a gate insulating layer GI may be disposed between the channel region CHA of the active pattern ATV and the third pattern OXP3. In this case, the third pattern OXP3 may serve to supply oxygen to the gate insulating layer GI and the channel region CHA of the active pattern ATV disposed under the third pattern OXP3.

More specifically, the third pattern OXP3 may supply oxygen to the channel region CHA via the gate insulating layer GI disposed between the third pattern OXP3 and the channel region CHA. In this case, hydrogen in the channel region CHA of the active pattern ATV may move to the gate insulating layer GI disposed on the channel region CHA of the active pattern ATV by an additional heat treatment process or the like. The oxygen supplied to the gate insulating layer GI may move to the channel region CHA of the active pattern ATV. As the oxygen moves, a defect in the channel region CHA of the active pattern ATV may be removed, and generation of undesirable carriers in the channel region CHA of the active pattern ATV may be suppressed.

Accordingly, in the active pattern ATV including the oxide semiconductor material, even when a channel length of the channel region CHA is a relatively short (i.e., when a carrier movement path between the first conductor area DA1 and the second conductor area DA2 is relatively short), it is possible to secure a sufficient threshold voltage.

In an embodiment, a side surface of the gate electrode GE and a side surface of the third pattern OXP3 may be aligned with each other in a cross-sectional view. In other words, as shown in FIG. 7, the lower surface of the gate electrode GE may completely overlap the upper surface of the third pattern OXP3. Accordingly, a sufficient area of the third pattern OXP3 may be secured, and a sufficient amount of oxygen may be supplied from the third pattern OXP3 to the channel region CHA of the active pattern ATV.

In an embodiment, the side surface of the third pattern OXP3 and a side surface of the gate insulating layer GI disposed under the third pattern OXP3 may be aligned with each other in the cross-sectional view. In other words, as shown in FIG. 7, a lower surface of the third pattern OXP3 may completely overlap an upper surface of the gate insulating layer GI disposed under the third pattern OXP3. Accordingly, a sufficient area of the third pattern OXP3 may be secured, and a sufficient amount of oxygen may be supplied from the third pattern OXP3 to the channel region CHA of the active pattern ATV.

Referring to FIGS. 7 and 8, the first electrode E1 may electrically contact the first lower electrode BE1 through a through hole formed through the gate insulating layer GI and the buffer layer BUF. The through hole may partially expose the first lower electrode BE1 and may be referred to as a first lower electrode through hole TH_BE1. In this case, the first lower electrode contact portion CT_BE1 may be a part of the first electrode E1 which is disposed in the first lower electrode through hole TH_BE1.

In an embodiment, the first opening OP1 defined in the first pattern OXP1 may completely expose the first lower electrode contact portion CT_BE1 in the plan view. In this case, as shown in FIGS. 5 and 6, the edge of the first opening OP1 and the edge of the first lower electrode through hole TH_BE1 may be spaced apart from each other, and the edge of the first opening OP1 may surround the edge of the first lower electrode through hole TH_BE1 in the plan view.

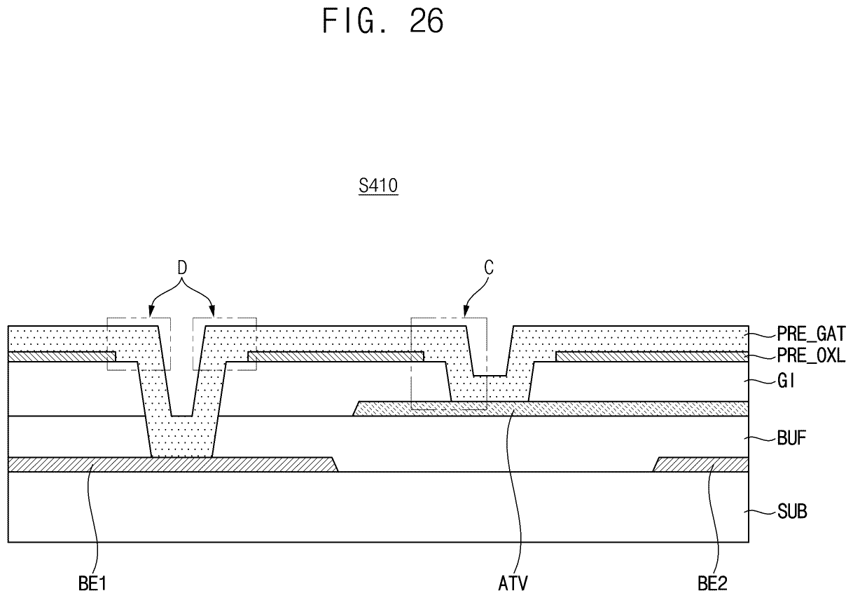

Accordingly, as shown in FIG. 8, the first pattern OXP1 is removed in an area AA between the edge of the first opening OP1 and the edge of the first lower electrode through hole TH_BE1, an aspect ratio of the first lower electrode through hole TH_BE1 may decrease and the first electrode E1 may directly contact the upper surface of the gate insulating layer GI. Therefore, a step coverage of the first electrode E1 may increase and a defect in the first electrode E1 may be prevented. The defect, for example, a contact defect, will be described later with reference to FIG. 26.

Referring back to FIG. 7, the second electrode E2 may electrically contact the second lower electrode BE2 through a through hole formed through the gate insulating layer GI and the buffer layer BUF. The through hole may partially expose the second lower electrode BE2 and may be referred to as a second lower electrode through hole TH_BE2. In this case, the second electrode E2 may include a second lower electrode contact portion CT_BE2 which is disposed in the second lower electrode through hole TH_BE2.

In an embodiment, the second opening OP2 defined in the second pattern OXP2 may completely expose the second lower electrode through hole TH_BE2 in the plan view. In this case, as shown in FIGS. 5 and 6, the edge of the second opening OP2 and the edge of the second lower electrode through hole TH_BE2 may be spaced apart from each other and the edge of second opening OP2 may surround the edge of the second lower electrode through hole TH_BE2 in the plan view.

Accordingly, the second pattern OXP2 is removed in an area between the edge of the second opening OP2 and the edge of the second lower electrode through hole TH_BE2, an aspect ratio of the second lower electrode through hole TH_BE2 may decrease and the second electrode E2 may directly contact the upper surface of the gate insulating layer GI. Therefore, a step coverage of the second electrode E2 may increase and a defect in the second electrode E2 may be prevented.

Referring to FIGS. 7 and 9, the first electrode E1 may electrically contact the first conductor region DA1 of the active pattern ATV by extending along the first side surface of the gate insulating layer GI. In this case, the first active contact portion CTla_ATV may be a part of the first electrode E1 extending along the first side surface of the gate insulating layer GI and electrically contacting the first conductor region DA1.

In an embodiment, in the plan view, the first groove GR1a defined in the first pattern OXP1 may surround at least a part of the first active contact portion CTla_ATV. In this case, as shown in FIGS. 5 and 6, the edge of the first pattern OXP1 defining the first groove GR1a and the edge of the first active contact portion CTla_ATV may be spaced apart from each other.

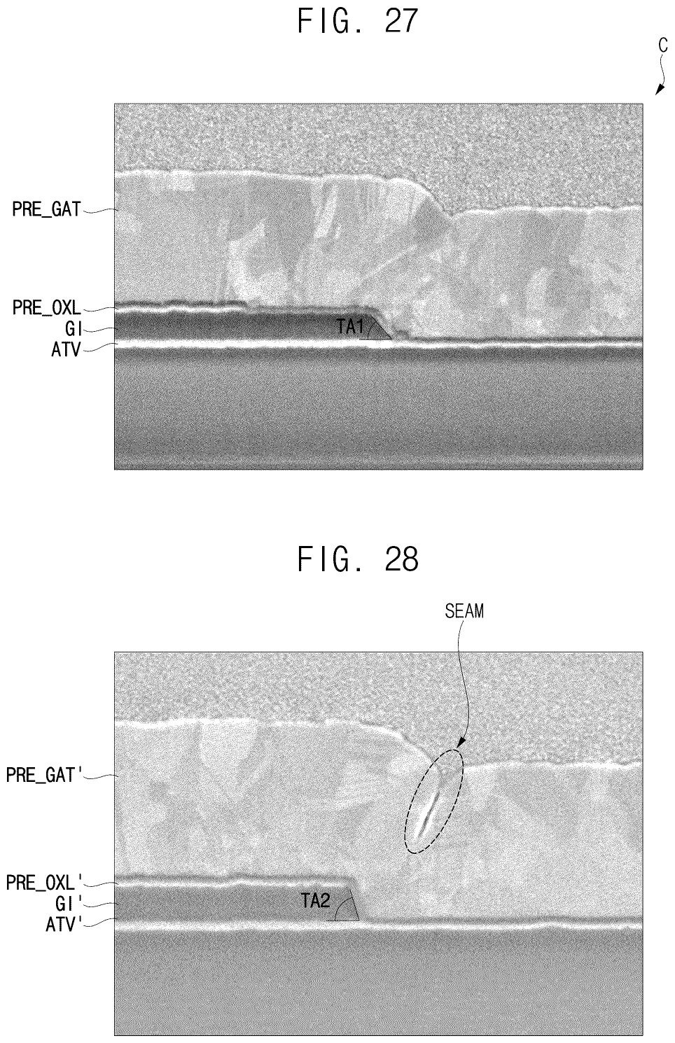

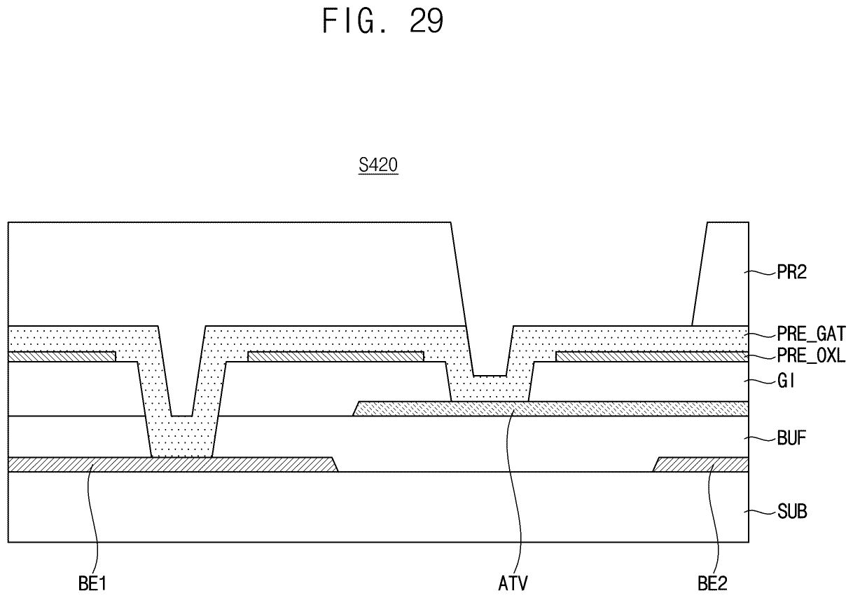

Accordingly, as shown in FIG. 9, in an area BB between the edge of the first pattern OXP1 defining the first groove GR1a and the edge of the first active contact portion CT1a_ATV, the first electrode E1 may directly contact the upper surface of the gate insulating layer GI. Therefore, contact defect may not occur between the first electrode E1 and the first conductor area DA1 of the active pattern ATV. The contact defect will be described later with reference to FIGS. 27 and 28.

In an embodiment, an average taper angle of the first side surface of the gate insulating layer GI with respect to the upper surface of the active pattern ATV may be about 65 degrees or less and about 30 degrees or more. Accordingly, the contact defect may not occur between the first electrode E1 and the first conductor area DA1 of the active pattern ATV. This will be described later with reference to FIGS. 27 and 28.

Referring back to FIG. 7, the second electrode E2 may electrically contact the second conductor region DA2 of the active pattern ATV by extending along the second side surface of the gate insulating layer GI. In this case, the second contact portion CT2a_ATV may be a part of the second electrode E2 extending along the second side surface of the gate insulating layer GI and electrically contacting the second conductor region DA2.

In an embodiment, in the plan view, the second groove GR2a defined in the second pattern OXP2 may surround at least a part of the second contact portion CT2a_ATV. In this case, as shown in FIGS. 5 and 6, the edge of the second pattern OXP2 defining the second groove GR2a and the edge of the second contact portion CT2a_ATV may be spaced apart from each other.

Accordingly, in an area between the edge of the second pattern OXP2 defining the second groove GR2a and the edge of the second contact portion CT2a_ATV, the second electrode E2 may directly contact the upper surface of the gate insulating layer GI. Therefore, a contact defect may not occur between the second electrode E2 and the second conductor area DA2 of the active pattern ATV.

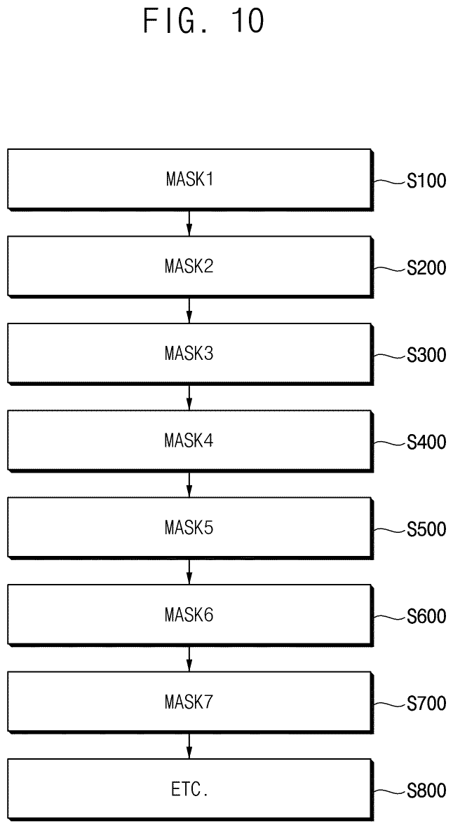

Hereinafter, a method of manufacturing the display device of FIG. 2 will be described with reference to FIGS. 10 to 43. In the descriptions with reference to FIGS. 10 to 43, the description of the first electrode E1 and the first pattern OXP1 disposed under the first electrode E1 may be similarly applied to the second electrode E2 and the second pattern OXP2 disposed under the second electrode E2. Therefore, in the following, for convenience of description, description of the second electrode E2 and the second pattern OXP2 disposed under the second electrode E2 may be omitted.

FIG. 10 is a flowchart illustrating a method of manufacturing a display device.

Referring to FIGS. 2 and 10, the method of manufacturing the display device may include the method of manufacturing the pixel PX described with reference to FIG. 2. In this case, the manufacturing method of the display device may include first, second, third, fourth, fifth, sixth, seventh, and eighth steps S100, S200, S300, S400, S500, S600, S700, and S800.

Each of first, second, third, fourth, fifth, sixth, and seventh steps S100, S200, S300, S400, S500, S600, and S700 may include at least one process. In this case, only one mask may be used in each of the first, second, third, fourth, fifth, sixth, and seventh steps S100, S200, S300, S400, S500, S600, and S700. For example, a first mask MASK1 may be used in the first step S100 and a second mask MASK2 may be used in the second step S200.

By performing the first, second, third, fourth, fifth, sixth, and seventh steps S100, S200, S300, S400, S500, S600, and S700, the lower electrode layer BML, the buffer layer BUF, the active pattern ATV, the gate insulating layer GI, the oxygen supply layer OXL, the gate electrode layer GAT, the passivation layer PVX, the via insulating layer VIA, the pixel electrode PXE, and the pixel defining layer PDL described with reference to FIG. 2 may be formed. In addition, by performing the eighth step S800, the light emitting layer EL and the common electrode layer CE described with reference to FIG. 2 may be formed.

As described above, in the manufacturing method of the display device of the present disclosure, by using only seven masks MASK1, MASK2, MASK3, MASK4, MASK5, MASK6, and MASK7, the lower electrode layer BML, the buffer layer BUF, the active pattern ATV, the gate insulating layer GI, the oxygen supply layer OXL, the gate electrode layer GAT, the passivation layer PVX, the via insulating layer VIA, the pixel electrode PXE, and the pixel defining layer PDL may be formed.

Accordingly, since the pixel PX can be manufactured using a relatively small number of masks, the process efficiency of the pixel PX manufacturing process can be improved.

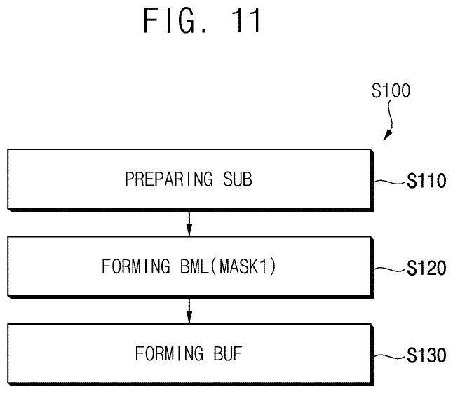

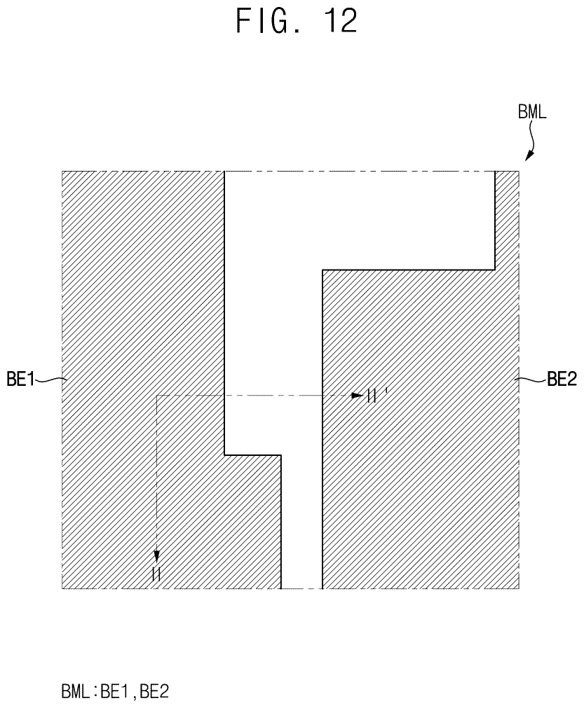

FIG. 11 is a flowchart for explaining the first step S100.

Referring to FIG. 11, the first step S100 may include preparing a substrate SUB (S110), forming the lower electrode layer BML on the substrate SUB (S120), and forming the buffer layer BUF entirely covering the substrate SUB and the lower electrode layer BML (S130).

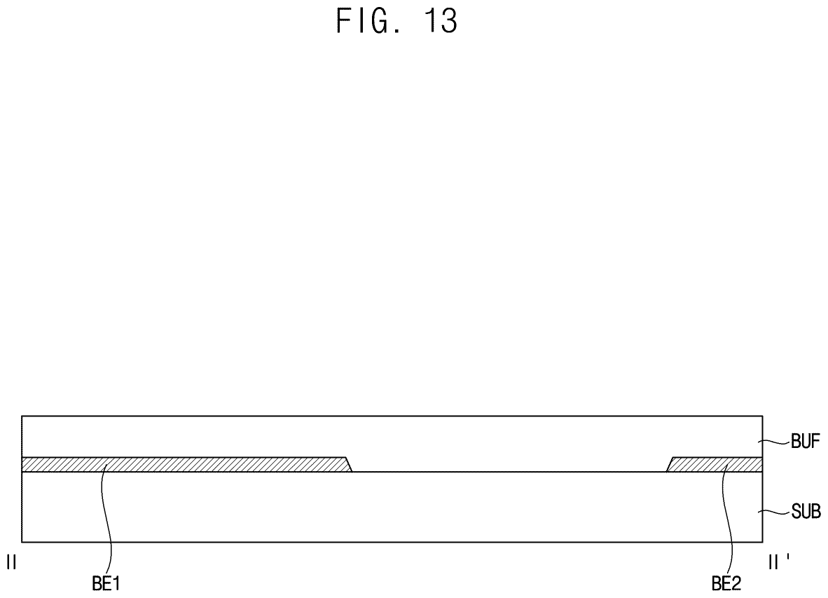

FIGS. 12 and 13 are views for explaining the first step S100 of FIG. 11.

Referring to FIGS. 11 to 13, the lower electrode layer BML may include the first lower electrode BE1 and the second lower electrode BE2. In this case, in the forming the lower electrode layer BML (S120), the conductive material is formed entirely on the substrate SUB, and the first lower electrode BE1 and the second lower electrode BE2 may be formed by patterning the conductive material using the first mask MASK1.

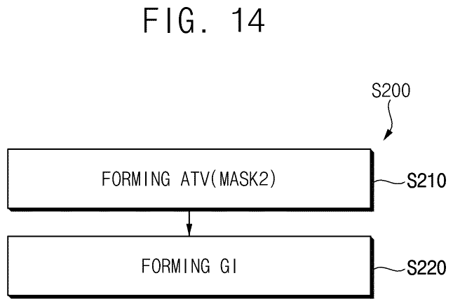

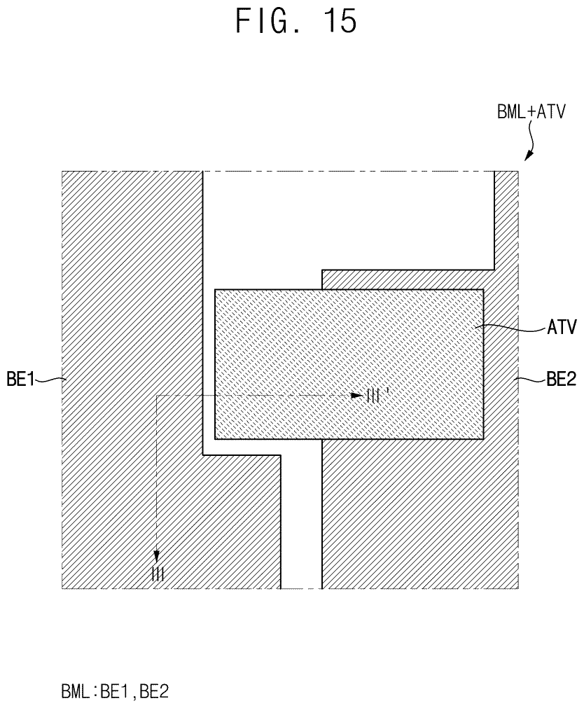

FIG. 14 is a flowchart for explaining the second step S200.

Referring to FIG. 14, the second step S200 may include forming the active pattern ATV on the buffer layer BUF (S210) and forming the gate insulating layer GI entirely covering the buffer layer BUF and the active pattern ATV (S220).

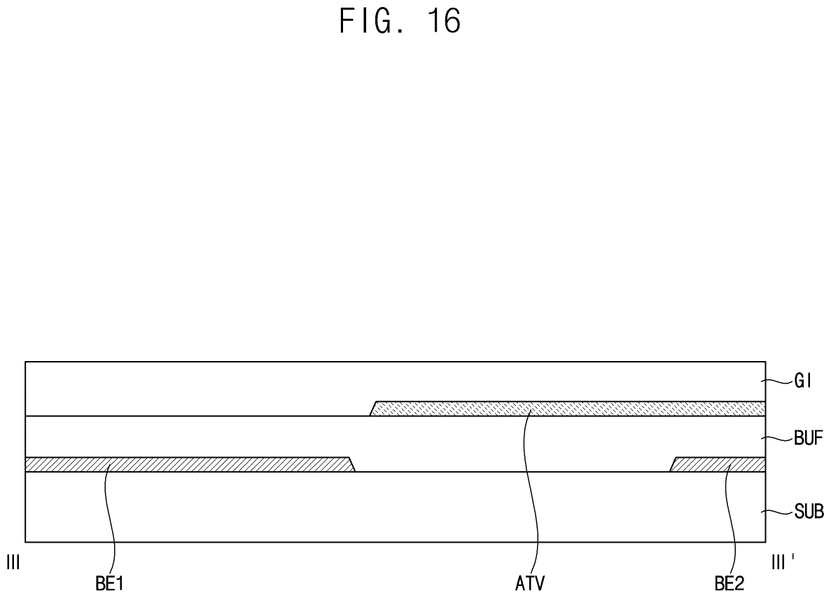

FIGS. 15 and 16 are diagrams for explaining the second step S200 of FIG. 14.

Referring to FIGS. 14 to 16, in the forming of the active pattern ATV (S210), the oxide semiconductor material is entirely formed on the buffer layer BUF, and the active pattern ATV may be formed by patterning the oxide semiconductor material using the second mask MASK2.

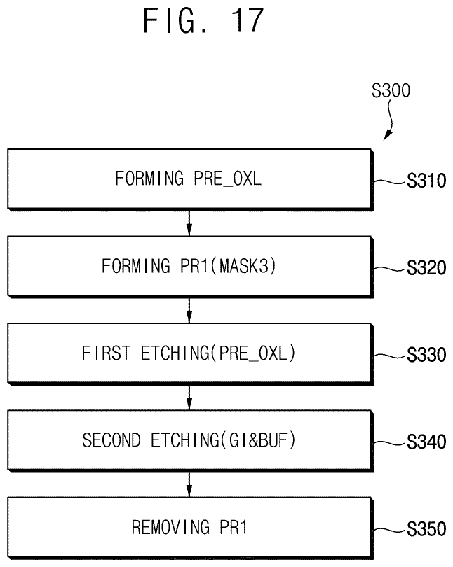

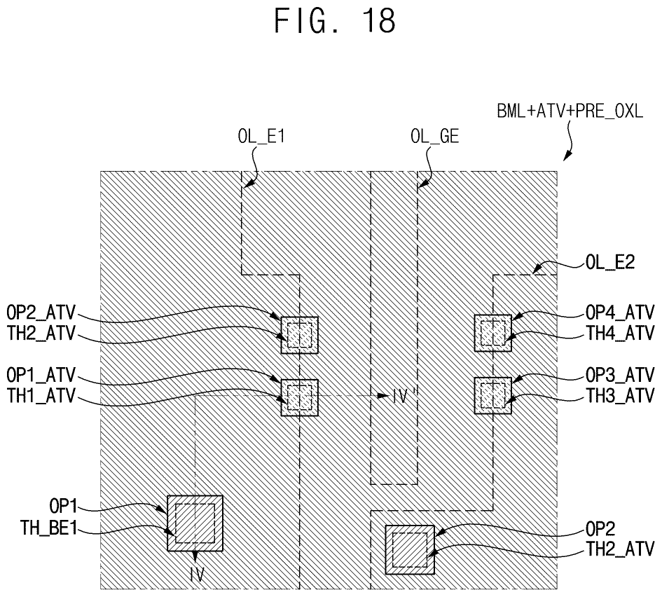

FIG. 17 is a flowchart for explaining the third step S300.

Referring to FIG. 17, the third step S300 may include forming a preliminary oxygen supply layer PRE_OXL entirely covering the gate insulating layer GI (S310), forming a first photoresist pattern PR1 on the preliminary oxygen supply layer PRE_OXL (S320), etching the preliminary oxygen supply layer PRE_OXL using the first photoresist pattern PR1 as a mask (S330), etching the gate insulating layer GI and the buffer layer BUF using the first photoresist pattern PR1 as a mask (S340), and removing the first photoresist pattern PR1 (S350).

FIGS. 18 to 23 are views for explaining the third step S300.

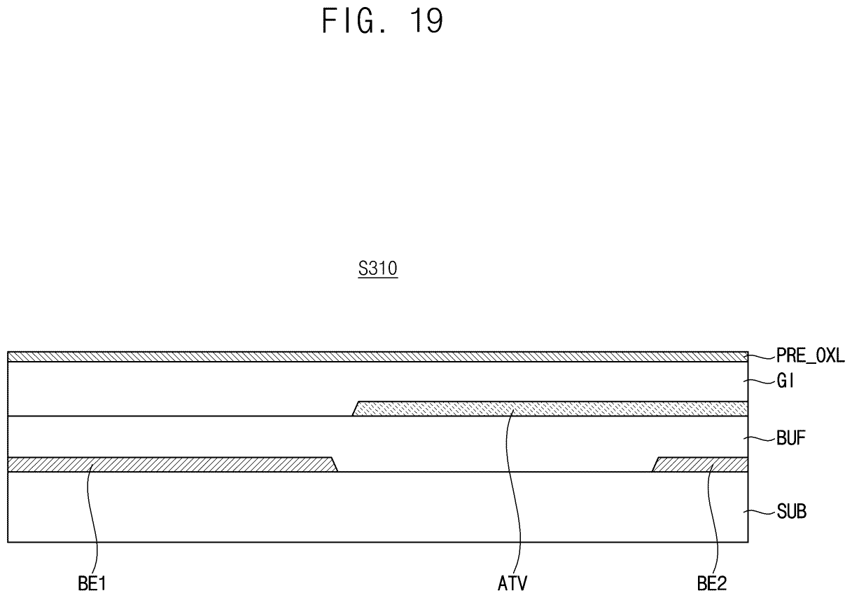

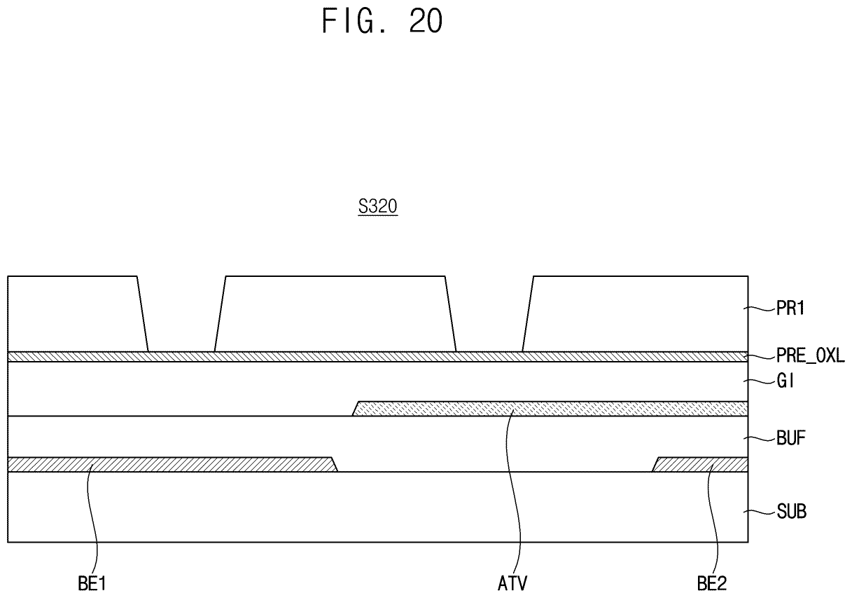

Referring to FIGS. 18 and 19, the preliminary oxygen supply layer PRE_OXL may be entirely formed on the gate insulating layer GI (S310). For example, an oxide semiconductor material may be entirely formed on the gate insulating layer GI.

Referring to FIGS. 18 and 20, the first photoresist pattern PR1 may be formed on the preliminary oxygen supply layer PRE_OXL (S320). In this case, a plurality of exposure openings exposing the preliminary oxygen supply layer PRE_OXL may be defined in the first photoresist pattern PR1. The plurality of exposure openings may be formed to correspond to the plurality of openings OP1, OP2, OP1_ATV, OP2_ATV, OP3_ATV, and OP4_ATV defined in the preliminary oxygen supply layer PRE_OXL shown in FIG. 18.

The third mask MASK3 may be used to form the first photoresist pattern PR1. More specifically, the first photoresist pattern PR1 including the plurality of exposure openings may be formed by forming the first photoresist material entirely covering the preliminary oxygen supply layer PRE_OXL, exposing an area corresponding to the plurality of exposure openings (or, exposing an area that does not correspond to the plurality of exposure openings) using the third mask MASK3 and then removing the exposed area (or, the unexposed area).

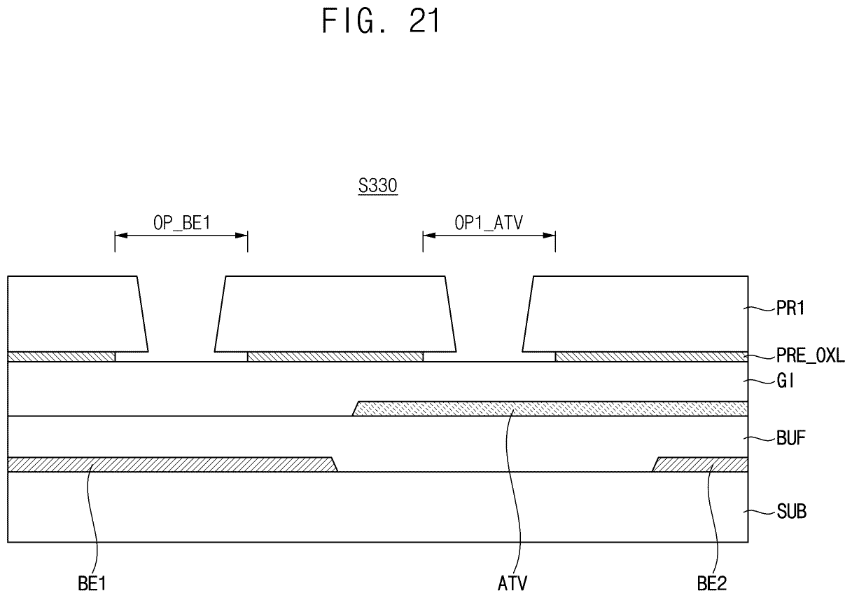

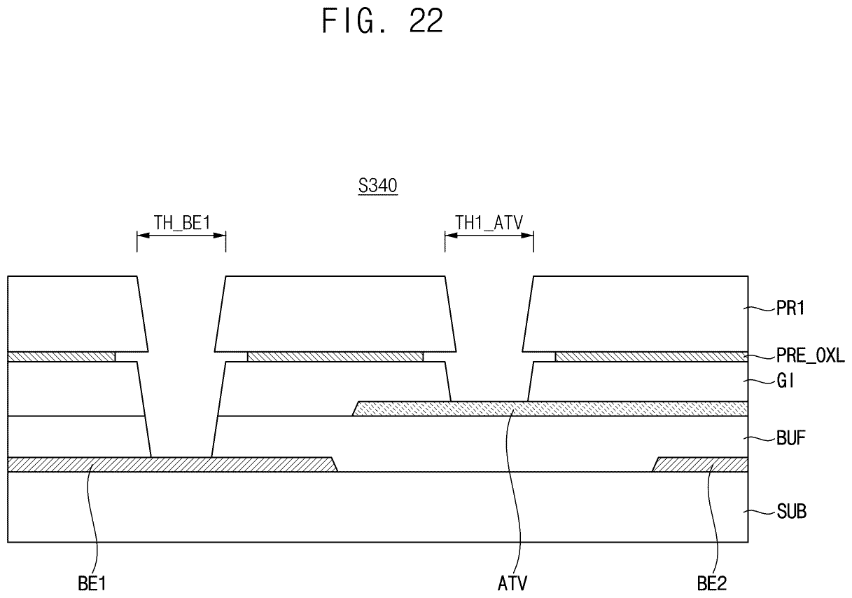

Referring to FIGS. 18 and 21, the preliminary oxygen supply layer PRE_OXL may be etched using the first photoresist pattern PR1 as a mask (S330). For example, the preliminary oxygen supply layer PRE_OXL may be isotropic etched, for example, wet etched, using the first photoresist pattern PR1 as a mask. In this case, the preliminary oxygen supply layer PRE_OXL may have an undercut portion under the first photoresist pattern PR1.

As the preliminary oxygen supply layer PRE_OXL has the undercut portion, a part of the preliminary oxygen supply layer PRE_OXL disposed under the first photoresist pattern PR1 may be removed and a plurality of openings formed through the preliminary oxygen supply layer PRE_OXL in a thickness direction may be formed.

For example, as the preliminary oxygen supply layer PRE_OXL is exposed to the etchant through a first exposure opening defined in the first photoresist pattern PR1, the first opening OP1 may be formed. In this case, since the preliminary oxygen supply layer PRE_OXL is isotropic etched to have the undercut portion under the first photoresist pattern PR1, the first opening OP1 may have a larger area than the first exposure opening, as shown in FIG. 21.

For another example, as the preliminary oxygen supply layer PRE_OXL is exposed to the etchant through a second exposure opening defined in the first photoresist pattern PR1, the first active opening OP1_ATV may be formed. In this case, since the preliminary oxygen supply layer PRE_OXL is isotropic etched to have an undercut portion formed under the first photoresist pattern PR1, the first active opening OP1_ATV may have a larger area than the second exposure opening, as shown in FIG. 21.

Similarly, the second, third, and fourth active openings OP2_ATV, OP3_ATV, and OP4_ATV and the second opening OP2 may be formed in the preliminary oxygen supply layer PRE_OXL.

In this case, as shown in FIG. 18, the first opening OP1 may be formed at a position overlapping the first lower electrode BE1, the second opening OP2 may be formed at a position overlapping the second lower electrode BE2, and the first, second, third, and fourth active openings OP1_ATV, OP2_ATV, OP3_ATV, and OP4_ATV may be formed at positions overlapping the active pattern ATV.

Referring to FIGS. 18 and 22, the gate insulating layer GI and the buffer layer BUF may be etched using the first photoresist pattern PR1 as a mask (S340). For example, the gate insulating layer GI and the buffer layer BUF may be anisotropic etched, for example, dry etched, using the first photoresist pattern PR1 as a mask.

As described above with reference to FIG. 20, a plurality of exposure openings are defined in the first photoresist pattern PR1. In this case, the gate insulating layer GI and/or the buffer layer BUF corresponding to the plurality of exposure openings may be removed by ab anisotropic etching, for example, a dry etching.

For example, as the gate insulating layer GI and the buffer layer BUF are anisotropic etched through the first exposure opening, a first lower electrode through hole TH_BE1 disposed inside of the first opening OP1 may be formed. The first lower electrode through hole TH_BE1 may be formed through the gate insulating layer GI and the buffer layer BUF to expose the first lower electrode BE1.

In this case, since the first opening OP1 is formed by isotropic etching of the preliminary oxygen supply layer PRE_OXL, the first opening OP1 has a relatively large planar area. Accordingly, the first opening OP1 formed in the preliminary oxygen supply layer PRE_OXL may completely expose the first lower electrode through hole TH_BE1 in the plan view, and an area of the first opening OP1 may be larger than an area of the first lower electrode through hole TH_BE1 in the plan view.

In other words, as shown in FIG. 18, the edge of the first opening OP1 may completely surround the edge of the first lower electrode through hole TH_BE1, and the edge of the first opening OP1 may be spaced apart from the edge of the first lower electrode through hole TH_BE1.

For another example, as the gate insulating layer GI is anisotropic etched through the second exposure opening, a first active through hole TH1_ATV disposed inside of the first active opening OP1_ATV in a plan view may be formed. The first active through hole TH1_ATV may be formed through the gate insulating layer GI to expose the active pattern ATV.

In this case, as the first active opening OP1_ATV is formed by isotropic etching the preliminary oxygen supply layer PRE_OXL, the first active opening OP1_ATV has a relatively large planar area. Accordingly, the first active opening OP1_ATV formed in the preliminary oxygen supply layer PRE_OXL may completely expose the first active through hole TH1_ATV in the plan view, and an area of the first active opening OP1_ATV may be larger than an area of the first active through hole TH1_ATV in the plan view.

In other words, as shown in FIG. 18, the edge of the first active opening OP1_ATV may surround the edge of the first active through hole TH1_ATV, and the edge of the first active opening OP1_ATV may be spaced apart from the edge of the first active through hole TH1_ATV.

Similarly, a second lower electrode through hole TH_BE2 disposed inside of the second opening OP2 may be formed, and second, third, and fourth active through-holes TH2_ATV, TH3_ATV, and TH4_ATV may be formed inside of the second, third, and fourth active openings OP2_ATV, OP3_ATV, and OP4_ATV.

The second lower electrode through hole TH_BE2 may be formed through the gate insulating layer GI and the buffer layer BUF to expose the second lower electrode BE2. In this case, the second opening OP2 may completely expose the second lower electrode through hole TH_BE2 in the plan view.

Each of the second, third, and fourth active through holes TH2_ATV, TH3_ATV, and TH4_ATV may be formed through the gate insulating layer GI to expose the active pattern ATV. In this case, the second, third, and fourth active openings OP2_ATV, OP3_ATV, and OP4_ATV may completely expose the second, third, and fourth active through holes TH2_ATV, TH3_ATV, and TH4_ATV in the plan view.

When the first, second, third, and fourth active through holes TH1_ATV, TH2_ATV, TH3_ATV, and TH4_ATV are formed by removing the gate insulating layer GI by the anisotropic etching, the active pattern ATV exposed by the first, second, third, and fourth active through holes TH1_ATV, TH2_ATV, TH3_ATV, and TH4_ATV, may be doped. Accordingly, electrical conductivity of the active pattern ATV exposed by the first, second, third, and fourth active through holes TH1_ATV, TH2_ATV, TH3_ATV, and TH4_ATV may be relatively increased.

In an embodiment, the active pattern ATV exposed by the first and second active through holes TH1_ATV and TH2_ATV may define a part of the first conductor area DA1 described with reference to FIG. 4.

In an embodiment, the active pattern ATV exposed by the third and fourth through holes TH3_ATV and TH4_ATV may define a part of the second conductor area DA2 described with reference to FIG. 4.

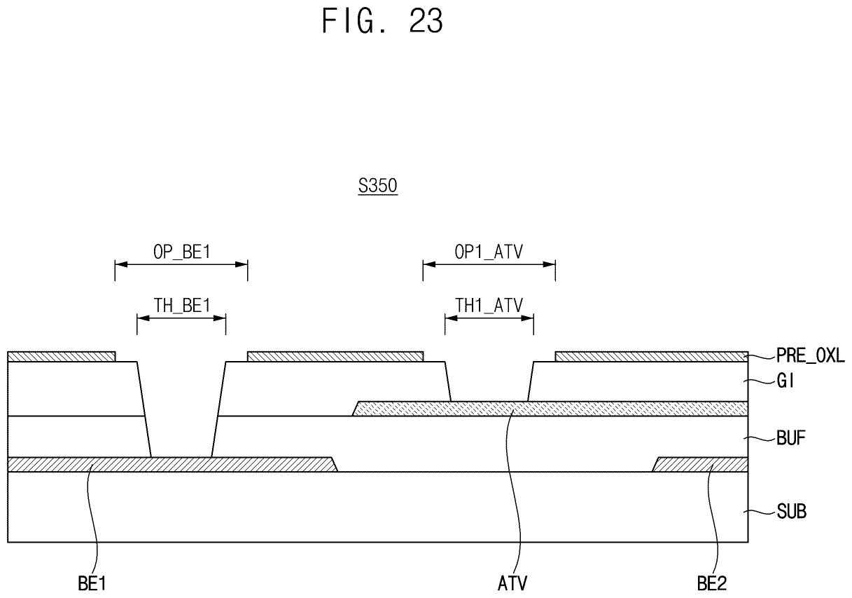

Referring to FIGS. 18 and 23, the first photoresist pattern PR1 may be removed (S350). A method of removing the first photoresist pattern PR1 is not limited to any specific method, and various known methods may be used.

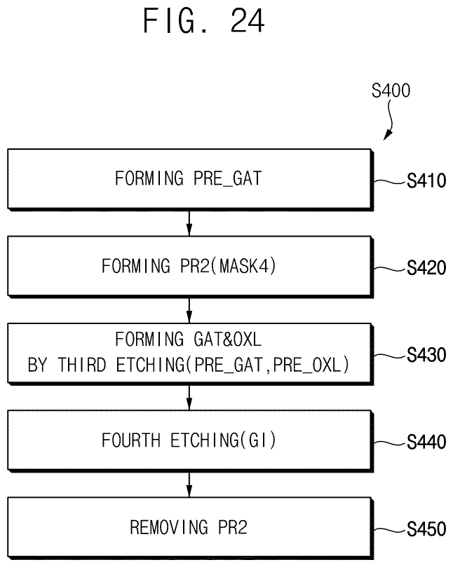

FIG. 24 is a flowchart for explaining the fourth step S400.

Referring to FIG. 24, the fourth step S400 may include forming a preliminary gate electrode layer PRE_GAT entirely covering the preliminary oxygen supply layer PRE_OXL (S410), forming a second photoresist pattern PR2 on the preliminary gate electrode layer PRE_GAT (S420), forming the oxygen supply layer OXL and the gate electrode layer GAT by etching the preliminary oxygen supply layer PRE_OXL and the preliminary gate electrode layer PRE_GAT using the second photoresist pattern PR2 as a mask (S430), etching the gate insulating layer GI using the second photoresist pattern PR2 as a mask (S440), and removing the second photoresist pattern PR2 (S450).

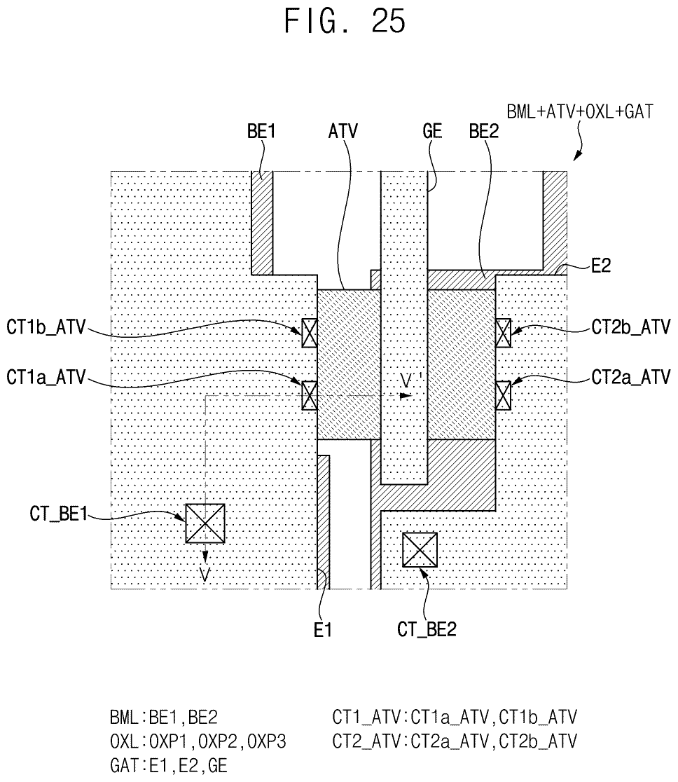

FIGS. 25 to 32 are views for explaining the fourth step S400 of FIG. 24.

Referring to FIGS. 25 to 28, the preliminary gate electrode layer PRE_GAT may be entirely formed to cover the preliminary oxygen supply layer PRE_OXL (S410). For example, after step S350 described with reference to FIG. 23, a conductive material may be entirely formed on the preliminary oxygen supply layer PRE_OXL.

In this case, as shown in FIG. 26, the preliminary gate electrode layer PRE_GAT may be formed to have a relatively uniform thickness along a cross-sectional profile of the first lower electrode BE1, the buffer layer BUF, the active pattern ATV, and the gate insulating layer GI.

The preliminary gate electrode layer PRE_GAT may contact the first lower electrode BE1 through the first lower electrode through hole TH_BE1 and may contact the active pattern ATV through the first active through hole TH1_ATV. Similarly, although not shown in FIG. 26, the preliminary gate electrode layer PRE_GAT may contact the second lower electrode BE2 through the second lower electrode through hole TH_BE2, and the preliminary gate electrode layer PRE_GAT may contact the active pattern ATV through the second, third, and fourth active through holes TH2_ATV, TH3_ATV, and TH4_ATV.

In this case, in the present disclosure, as the preliminary oxygen supply layer PRE_OXL is formed to have an undercut so that the first active opening OP1_ATV (see FIG. 23) has a relatively large area, contact defect may not occur in the preliminary gate electrode layer PRE_GAT contacting the active pattern ATV through the first active through hole TH1_ATV.

More specifically, referring to FIG. 27, which is an image of area C of FIG. 26, as the preliminary oxygen supply layer PRE_OXL is isotropic etched to have the undercut, a part of the upper surface of the gate insulating layer GI may not be covered by the preliminary oxygen supply layer PRE_OXL. In this case, after the dry etching step (S340, see FIG. 22) in which the first active through hole TH1_ATV is formed, an average taper angle TA1 of the side surface of the gate insulating layer GI disposed in the area C with respect to the upper surface of the active pattern ATV may be relatively small. For example, the average taper angle TA1 may be about 65 degrees or less and about 30 degrees or more.

In contrast, assuming that the preliminary oxygen supply layer PRE_OXL is not isotropic etched in the step S330 (see FIG. 21), the first active opening OP1_ATV and the first active through hole TH1_ATV may form substantially single sidewall which does not include a stepped portion.

More specifically, assuming that the preliminary oxygen supply layer PRE_OXL is not isotropic etched, as shown in FIG. 28, in area C, the preliminary oxygen supply layer PRE_OXL′ may substantially completely cover the upper surface of the gate insulating layer GI′. In this case, when forming the first active through hole TH1_ATV by anisotropic etching the gate insulating layer GI in the step (S340, see FIG. 22) performed after the step (S330, see FIG. 21), the preliminary oxygen supply layer PRE_OXL′ that is not isotropic etched may serve as a mask in the dry etching process. Accordingly, an average taper angle TA2 of the side surface of the gate insulating layer GI′ disposed in the area C with respect to the upper surface of the active pattern ATV′ may be relatively large.

Accordingly, when the preliminary gate electrode layer PRE_GAT′ is formed in the subsequent step (S410, see FIG. 26), due to the relatively large average taper angle TA2 and higher aspect ratio of the active through hole, a portion having a poor step coverage SEAM may be formed in the preliminary gate electrode layer PRE_GAT′. Accordingly, when the first electrode E1 is formed by removing a part of the preliminary gate electrode layer PRE_GAT′, the first electrode E1 may include the portion having the poor step coverage SEAM, and a defect may occur in the electrical connection between the first electrode E1 and the active pattern ATV.

In FIGS. 27 and 28, the description has been made based on the area C, but the contents described with reference to FIGS. 27 and 28 can be similarly applied to an area D. That is, in the present disclosure, a contact defective portion may not occur in the area D.

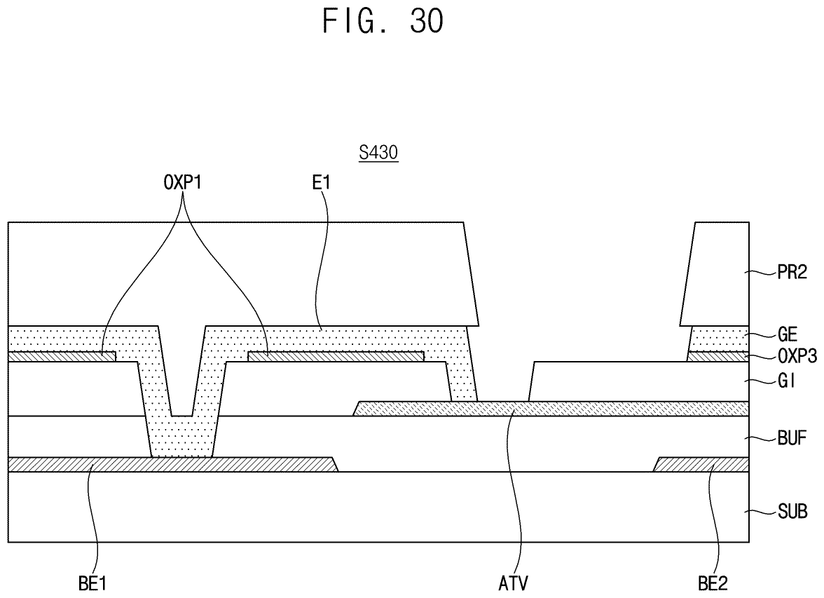

Referring to FIGS. 25 and 29, the second photoresist pattern PR2 may be formed on the preliminary gate electrode layer PRE_GAT (S420).

In this case, the fourth mask MASK4 may be used to form the second photoresist pattern PR2. A method of forming the second photoresist pattern PR2 using the fourth mask MASK4 may be substantially similar to the method of forming the first photoresist pattern PR1 using the third mask MASK3 described with reference to FIG. 20.

For example, after the photoresist material is entirely coated on the preliminary gate electrode layer PRE_GAT, the second photoresist pattern PR2 exposing a part of the preliminary gate electrode layer PRE_GAT may be formed by patterning the photoresist material using the fourth mask MASK4.

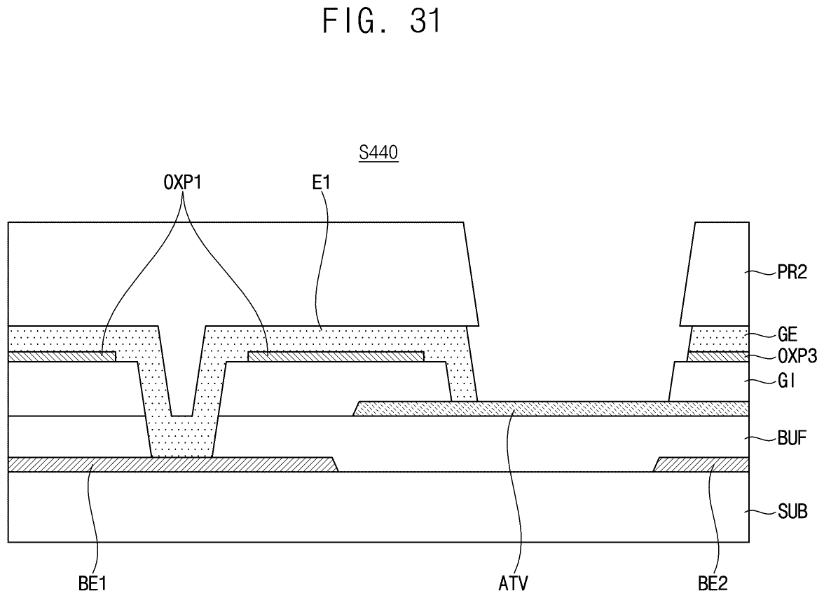

Referring to FIGS. 25 and 30, the oxygen supply layer OXL and the gate electrode layer GAT may be formed (S430). For example, the preliminary oxygen supply layer PRE_OXL and the preliminary gate electrode layer PRE_GAT may be wet etched using the second photoresist pattern PR2 as a mask.

More specifically, a part of the preliminary gate electrode layer PRE_GAT that does not covered by the second photoresist pattern PR2 may be removed by an etchant. Accordingly, as shown in FIG. 25, the gate electrode layer GAT including the first electrode E1, the second electrode E2, and the gate electrode GE may be formed.

In addition, a part of the preliminary oxygen supply layer PRE_OXL that does not overlap with the second photoresist pattern PR2 may be removed by the etchant. Accordingly, the oxygen supply layer OXL including the first pattern OXP1, the second pattern OXP2, and the third pattern OXP3 described with reference to FIG. 5 may be formed.

In this case, referring to FIG. 18 again, a first overlapping line OL_E1, a second overlapping line OL_E2, and a third overlapping line OL_GE indicated by dotted lines in FIG. 18 may represent overlapping boundaries between the preliminary oxygen supply layer PRE_OXL and the second photoresist pattern PR2.

For example, the preliminary oxygen supply layer PRE_OXL may be wet etched along the first overlapping line OL_E1 to form the first pattern OXP1 described with reference to FIG. 5. In this case, as shown in FIG. 18, the first overlapping line OL_E1 overlaps the first active opening OP1_ATV. Accordingly, as shown in FIG. 5, a part of the first active opening OP1_ATV defined in the preliminary oxygen supply layer PRE_OXL may define the first groove GR1a of the first pattern OXP1.

For example, the preliminary oxygen supply layer PRE_OXL may be wet etched along the second overlapping line OL_E2 to form the second pattern OXP2 described with reference to FIG. 5. In this case, as shown in FIG. 18, the second overlapping line OL_E2 overlaps the third active opening OP3_ATV. Accordingly, as shown in FIG. 5, a part of the third active opening OP3_ATV defined in the preliminary oxygen supply layer PRE_OXL may define the second groove GR2a of the second pattern OXP3.

Similarly, the third pattern OXP3 described with reference to FIG. 5 may be formed by wet etching the preliminary oxygen supply layer PRE_OXL along the third overlapping line OL_GE. In this case, since the gate electrode GE and the third pattern OXP3 are simultaneously formed through the same wet etching process, as shown in FIG. 30, the side surface of the gate electrode GE and the side surface of the third pattern OXP3 may be aligned with each other.

In an embodiment, in the wet etching process, a part of the active pattern ATV not covered by the gate insulating layer GI may be removed by the etchant. Accordingly, a through hole (not shown) formed through the active pattern ATV in the thickness direction may be formed, or a recessed portion (not shown) may be formed from an upper surface of the active pattern ATV in the thickness direction in a partial area of the active pattern ATV. However, even in this case, the active pattern ATV and the first electrode E1 may be electrically connected by bypassing the through hole or the recessed portion.

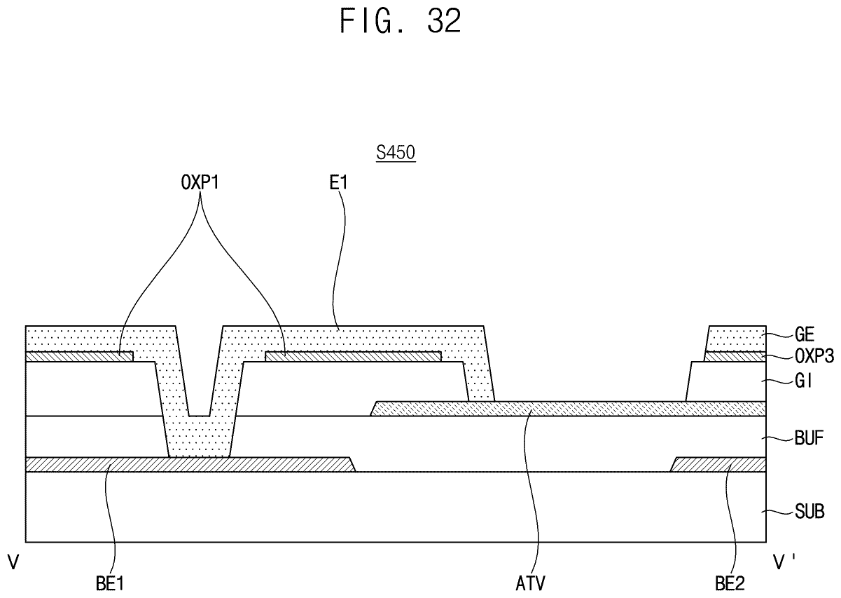

Referring to FIGS. 25 and 31, the gate insulating layer GI may be etched using the second photoresist pattern PR2 as a mask (S440). For example, the gate insulating layer GI may be dry etched using the second photoresist pattern PR2 as a mask.

In this case, since the gate insulating layer GI is dry etched using the second photoresist pattern PR2 as a mask, as shown in FIG. 31, the side surface of the gate insulating layer GI disposed under the third pattern OXP3 may protrude more than the side surface of the third pattern OXP3.

In addition, when a part of the gate insulating layer GI is removed by the dry etching, a part of the active pattern ATV overlapping the part of the gate insulating layer GI may be doped. The part of the doped active pattern ATV may define the first conductor region DA1 described with reference to FIG. 4 together with the active pattern ATV exposed by the first and second active through holes TH1_ATV and TH2_ATV described with reference to FIG. 20.

Likewise, the active pattern ATV exposed by the third and fourth through holes TH3_ATV and TH4_ATV described with reference to FIG. 20 may define the first conductor region DA1 described with reference to FIG. 4 together with another part of the active pattern ATV doped by the dry etching.

Referring to FIGS. 25 and 32, the second photoresist pattern PR2 may be removed. A method of removing the second photoresist pattern PR2 is not limited to a specific method, and various known methods may be used.

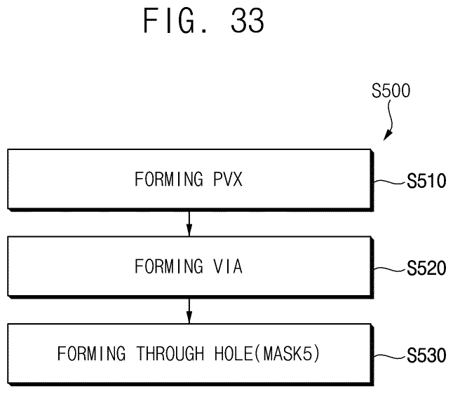

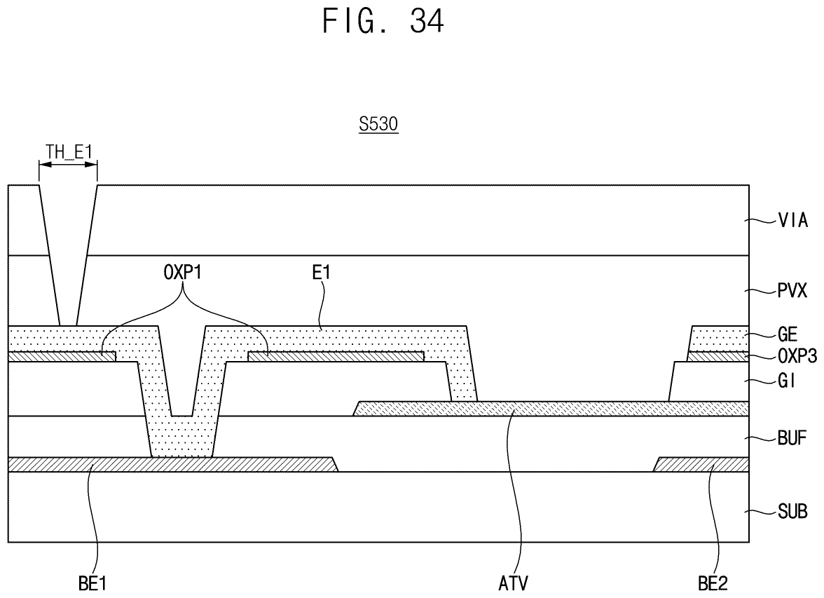

FIG. 33 is a flowchart for explaining the fifth step S500.

Referring to FIG. 33, the fifth step S500 may include forming the passivation layer PVX entirely on the first electrode E1 (S510), forming the via insulating layer VIA entirely on the passivation layer PVX (S520), and forming a through hole formed through the via insulating layer VIA and the passivation layer PVX (S530).

FIG. 34 is a cross-sectional view for explaining the fifth step S500 of FIG. 33.

Referring to FIG. 34, after sequentially forming the passivation layer PVX and the via insulation layer VIA (S510 and S520), a through hole TH_E1 exposing the first electrode E1 may be formed through the passivation layer PVX and the via insulation layer VIA. In this case, a fifth mask MASK5 may be used to form the through hole TH_E1. As a method of using the fifth mask MASK5 to form the through hole TH_E1, various known through hole forming methods may be used.

In FIG. 34, the through hole TH_E1 exposing the first electrode E1 is illustrated as an example, but the position of the through hole TH_E1 is not limited thereto. For example, instead of the through hole TH_E1, another through hole exposing the second electrode E2 may be formed through the passivation layer PVX and the via insulation layer VIA.

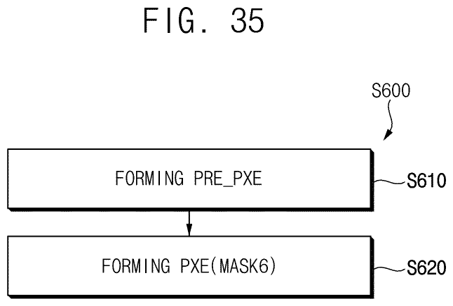

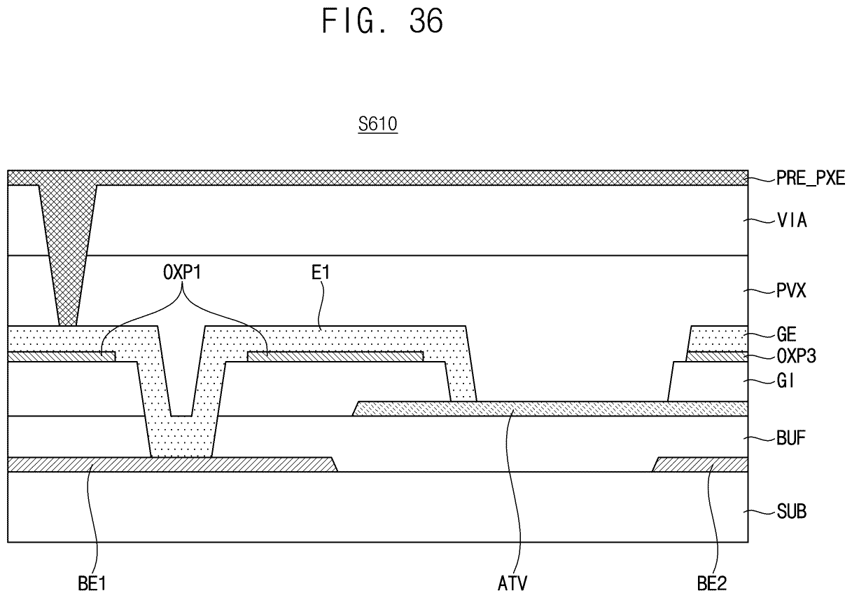

FIG. 35 is a flowchart for explaining the sixth step S600.

Referring to FIG. 35, the sixth step S600 may include forming a preliminary pixel electrode layer PRE_PXE entirely on the via insulating layer VIA (S610) and a forming the pixel electrode PXE by patterning the preliminary pixel electrode layer PRE_PXE (S620).

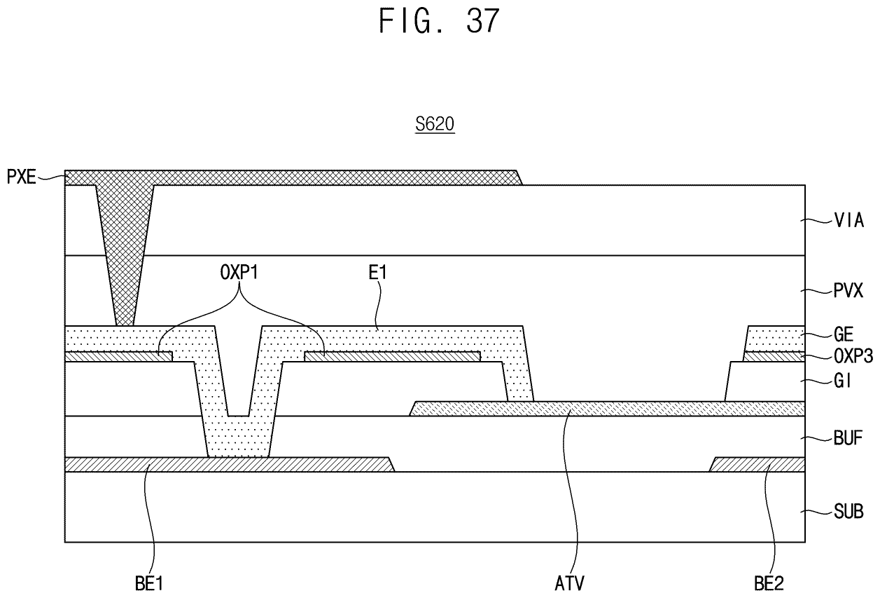

FIGS. 36 and 37 are cross-sectional views for explaining the sixth step S600 of FIG. 35.

Referring to FIG. 36, THE preliminary pixel electrode layer PRE_PXE may be entirely formed on the via insulating layer VIA (S610). In this case, the preliminary pixel electrode layer PRE_PXE may electrically contact the first electrode E1 through the through hole TH_E1.

Referring to FIG. 37, the pixel electrode PXE may be formed by patterning the preliminary pixel electrode layer PRE_PXE (S620). In this case, the sixth mask MASK6 may be used. A method of patterning the preliminary pixel electrode layer PRE_PXE using the sixth mask MASK6 is not limited to a specific method, and various known methods may be used.

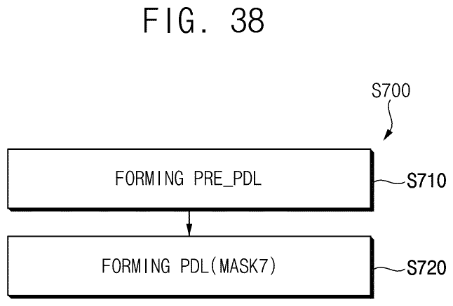

FIG. 38 is a flowchart for explaining the seventh step S700.

Referring to FIG. 38, the seventh step S700 may include forming a preliminary pixel definition layer PRE_PDL to entirely cover the pixel electrode PXE (S710) and forming the pixel defining layer PDL defining a pixel opening exposing at least a part of the pixel electrode PXE by patterning the preliminary pixel defining layer PRE_PDL (S720)

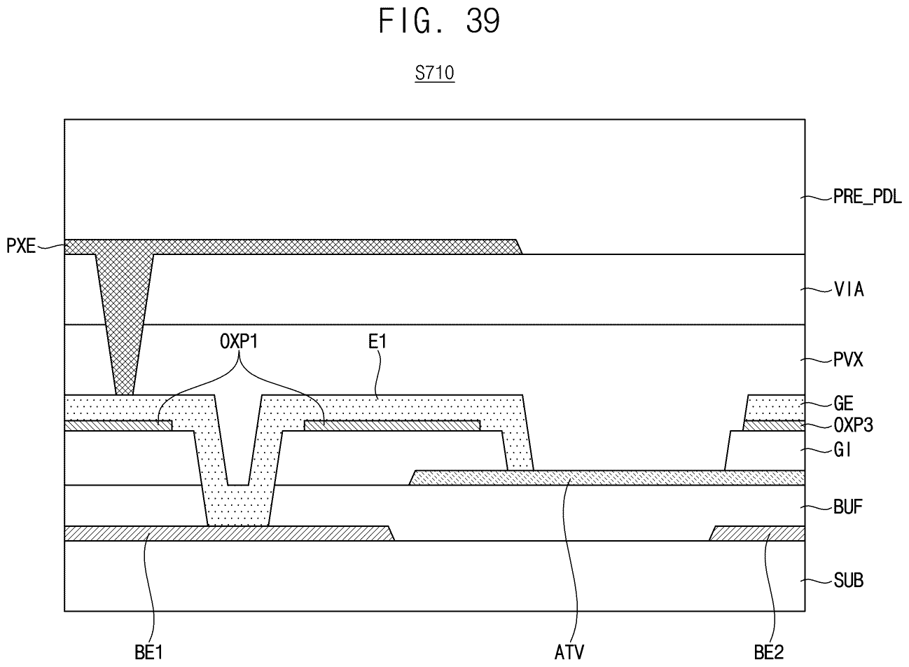

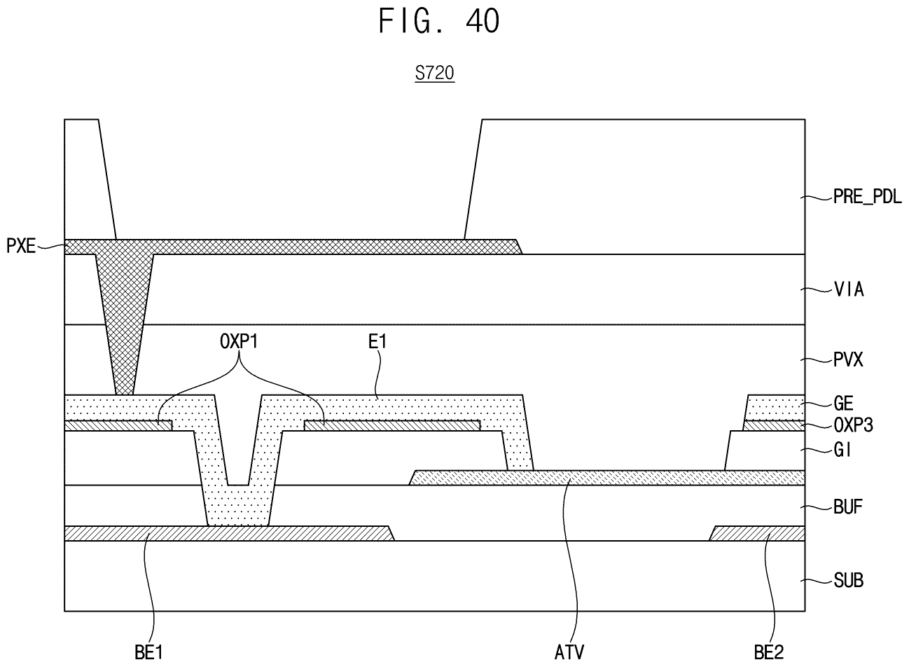

FIGS. 39 and 40 are cross-sectional views for explaining the seventh step S700 of FIG. 38.

Referring to FIG. 39, the preliminary pixel definition layer PRE_PDL may be entirely formed to cover the pixel electrode PXE (S710).

Referring to FIG. 40, the pixel defining layer PDL may be formed by patterning the preliminary pixel defining layer PRE_PLD (S720). The pixel defining layer PDL may define a pixel opening exposing at least a part of the pixel electrode PXE.

In this case, the seventh mask MASK7 may be used. A method of patterning the preliminary pixel definition layer PRE_PDL using the seventh mask MASK7 is not limited to a specific method, and various known methods may be used.

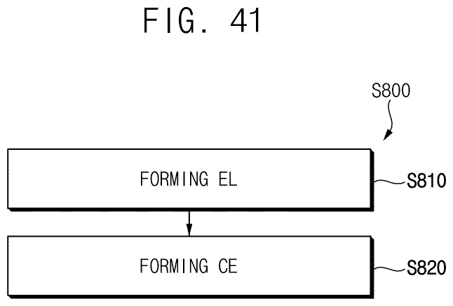

FIG. 41 is a flowchart for explaining the eighth step S800.

Referring to FIG. 41, the eighth step S800 may include forming the light emitting layer EL (S810) and forming the common electrode layer CE (S820).

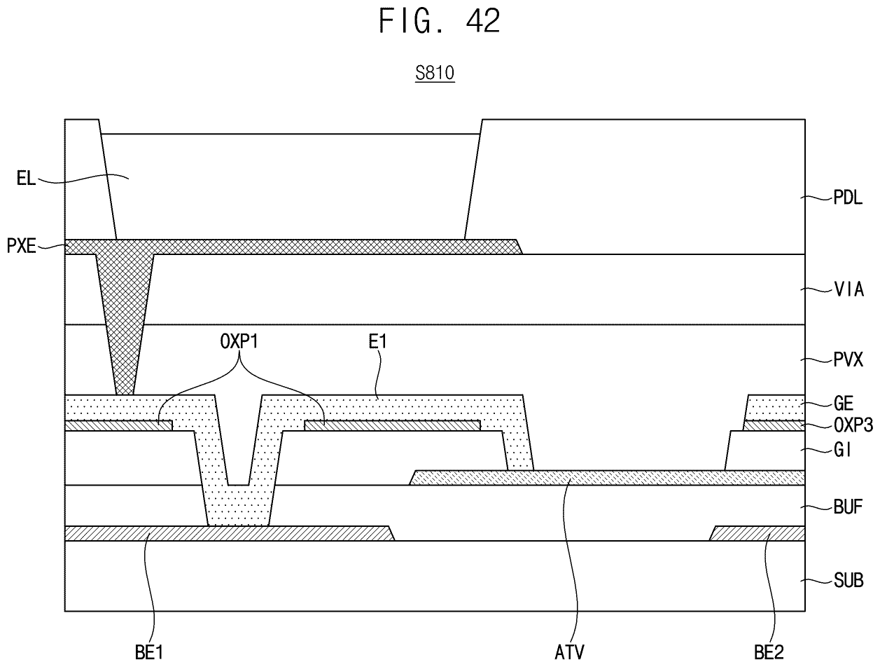

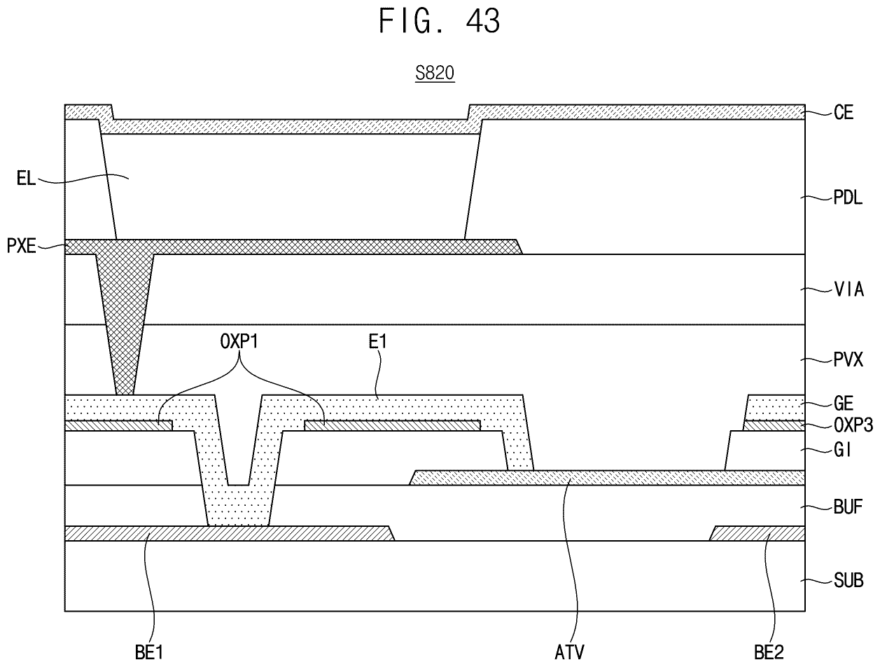

FIGS. 42 and 43 are cross-sectional views for explaining the eighth step S800 of FIG. 43.

Referring to FIG. 42, the light emitting layer EL may be formed on the pixel electrode PXE (S810). In an embodiment, the light emitting layer EL may be disposed in the pixel opening.

A method of forming the light emitting layer EL is not limited to a specific method, and various known methods may be used. For example, the light emitting layer EL may be deposited using a fine metal mask (FMM). For another example, the light emitting layer EL may be formed by an inkjet method without using a mask. That is, a mask is not necessarily used when forming the light emitting layer EL.

Referring to FIG. 43, the common electrode CE may be entirely formed to cover the light emitting layer EL and the pixel defining layer PDL. A method of forming the common electrode CE is not limited to specific method, and various known methods may be used.

The present disclosure can be applied to various display devices. For example, the present disclosure is applicable to various display devices such as display devices for vehicles, ships and aircraft, portable communication devices, display devices for exhibition or information transmission, medical display devices, and the like.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A display device comprising:
a buffer layer including an inorganic insulating material;
an active pattern disposed on the buffer layer and including a channel region and a first conductor region disposed adjacent to the channel region;
a gate insulating layer disposed on the buffer layer and the active pattern and including an inorganic insulating material;
a gate electrode layer including a first electrode which includes a first contact portion electrically contacting the first conductor region by extending along a side surface of the gate insulating layer; and
an oxygen supply layer including a first pattern disposed between the first electrode and the gate insulating layer,
wherein the first pattern includes a first groove recessed from a side surface of the first pattern to surround at least a part of the first contact portion in a plan view.

2. The display device of claim 1, wherein the first electrode directly contacts an upper surface of the gate insulating layer in an area between an edge of the first pattern defining the first groove and an edge of the first contact portion in the plan view.

3. The display device of claim 1, wherein an average taper angle of the side surface of the gate insulating layer with respect to an upper surface of the active pattern is about 65 degrees or less and about 30 degrees or more.

4. The display device of claim 1, further comprising:
a lower electrode layer disposed under the buffer layer and including a first lower electrode electrically connected to the first electrode.

5. The display device of claim 4, wherein the first electrode includes a first lower electrode contact portion electrically contacting the first lower electrode through a through hole formed through the gate insulating layer and the buffer layer, and
wherein the first pattern includes a first opening formed through the first pattern in a thickness direction and exposing the first lower electrode contact portion in the plan view.

6. The display device of claim 5, wherein the first electrode directly contacts an upper surface of the gate insulating layer in an area between an edge of the first opening and an edge of the first lower electrode contact portion in the plan view.

7. The display device of claim 1, wherein the active pattern further includes a second conductor region spaced apart from the first conductor region with the channel region interposed therebetween,
wherein the gate electrode layer further includes a second electrode which includes a second contact portion electrically contacting the second conductor region by extending along a side surface of the gate insulating layer and spaced apart from the first electrode,
wherein the oxygen supply layer further includes a second pattern disposed between the second electrode and the gate insulating layer and spaced apart from the first pattern, and
wherein a second groove recessed from a side surface of the second pattern to surround at least a part of the second contact portion is defined in the second pattern.

8. The display device of claim 7, wherein the second electrode directly contacts an upper surface of the gate insulating layer in an area between an edge of the second pattern defining the second groove and an edge of the second contact portion in the plan view.

9. The display device of claim 7, further comprising:
a lower electrode layer disposed under the buffer layer and including a second lower electrode electrically connected to the second electrode.

10. The display device of claim 9, wherein the second electrode includes a second lower electrode contact portion electrically contacting the second lower electrode through a through hole formed through the gate insulating layer and the buffer layer, and
wherein the second pattern includes a second opening formed through the second pattern in a thickness direction and overlapping the second lower electrode contact portion in the plan view.

11. The display device of claim 10, wherein the second electrode directly contacts an upper surface of the gate insulating layer in an area between an edge of the second opening and an edge of the second lower electrode contact portion in the plan view.

12. The display device of claim 1, wherein the second electrode further includes a gate electrode disposed to overlap the channel region, and
wherein the oxygen supply layer further includes a third pattern disposed between the gate electrode and the gate insulating layer.

13. The display device of claim 12, wherein a side surface of the third pattern is aligned with a side surface of the gate electrode in a cross-sectional view.

14. The display device of claim 13, wherein the side surface of the third pattern is recessed from a side surface of the gate insulating layer disposed under the third pattern.

15. The display device of claim 1, wherein each of the oxygen supply layer and the active pattern includes an oxide semiconductor material.

16. The display device of claim 1, wherein the oxygen supply layer directly contacts the gate electrode layer.

17. A method of manufacturing a display device, the method comprising:
forming an active pattern on a buffer layer;
forming a gate insulating layer on the buffer layer and the active pattern;
forming a preliminary oxygen supply layer on the gate insulating layer;
forming a first photoresist pattern on the preliminary oxygen supply layer;
isotropic etching the preliminary oxygen supply layer using the first photoresist pattern as a mask;
forming a first through hole exposing the active pattern through the gate insulating layer by etching the gate insulating layer using the first photoresist pattern as a mask;
removing the first photoresist pattern;
forming a preliminary gate electrode layer to entirely cover the preliminary oxygen supply layer;
forming a second photoresist pattern on the preliminary gate electrode layer; and
forming a first electrode including a first contact portion electrically contacting the active pattern by extending along a side surface of the gate insulating layer and a first pattern disposed between the first electrode and the gate insulating layer by etching the preliminary gate electrode layer and the preliminary oxygen supply layer using the second photoresist pattern as a mask.

18. The method of claim 17, wherein, in the isotropic etching the preliminary oxygen supply layer, the isotropic etched preliminary oxygen supply layer defines a first active opening completely exposing the first through hole in a plan view, and
an area of the first active opening is larger than an area of the first through hole in the plan view.

19. The method of claim 18, wherein, in the forming the first electrode and the first pattern, a first groove recessed from a side surface of the first pattern is defined in the first pattern to surround at least a part of the first contact portion, and
wherein the first groove is a part of the first active opening.

20. The method of claim 18, wherein, in the forming the first electrode and the first pattern, the first contact portion electrically contacts the active pattern by extending along a part of a side surface of the gate insulating layer defining the first through hole.

21. The method of claim 18, wherein, in the forming the preliminary gate electrode layer, the preliminary gate electrode layer directly contacts the gate insulating layer in an area between an edge of the first active opening and an edge of the first through hole in a plan view.

22. The method of claim 17, before the forming the active pattern, further comprising:
forming a lower electrode layer including a first lower electrode; and
forming the buffer layer to entirely cover the lower electrode layer.

23. The method of claim 22, wherein, in the isotropic etching the preliminary oxygen supply layer, a first opening formed through the preliminary oxygen supply layer in a thickness direction and at least partially overlapping the first lower electrode is further formed,
wherein, in the forming the first through hole, a first lower electrode through hole formed through the gate insulating layer and the buffer layer to expose the first lower electrode and is completely exposed by the first opening in a plan view is further formed, and
wherein an area of the first opening is larger than an area of the first lower electrode through hole in the plan view.

24. The method of claim 23, wherein, in the forming the preliminary gate electrode layer, the preliminary gate electrode layer directly contacts the gate insulating layer in an area between an edge of the first opening and an edge of the first lower electrode through hole in the plan view.

25. The method of claim 23, wherein, in the forming the first electrode and the first pattern, the first electrode electrically contacts the first lower electrode through the first lower electrode through hole.

26. The method of claim 17, wherein, in the forming the first electrode and the first pattern, a gate electrode spaced apart from the active pattern with the gate insulating layer interposed therebetween is further formed by etching the preliminary gate electrode layer,
wherein a third pattern disposed between the gate electrode and the gate insulating layer is further formed by etching the preliminary oxygen supply layer, and
wherein a side surface of the third pattern is aligned with a side surface of the gate electrode in a cross-sectional view.

27. The method of claim 26, further comprising:
etching the gate insulating layer using the second photoresist pattern as a mask after the forming the first electrode and the first pattern.

28. The method of claim 27, wherein, in the etching the gate insulating layer using the second photoresist pattern as the mask, the side surface of the third pattern is recessed from a side surface of the gate insulating layer disposed under the third pattern in the cross-sectional view.
